(19) United States
(12) Patent Application Publication
(10) Pub. No.: US 2025/0159929 A1
(43) Pub. Date: May 15, 2025

(54) SEMICONDUCTOR DEVICE

(71) Applicant: Samsung Electronics Co., Ltd., Suwon-si (KR)

(72) Inventors: Kyoung-Mi PARK, Suwon-si (KR); Hyo Jin KIM, Suwon-si (KR); Dong Hoon HWANG, Suwon-si (KR); Young Jin YANG, Suwon-si (KR); Kyung Hee CHO, Suwon-si (KR)

(73) Assignee: Samsung Electronics Co., Ltd., Suwon-si (KR)

(21) Appl. No.: 18/756,943

(22) Filed: Jun. 27, 2024

(30) Foreign Application Priority Data
Nov. 14, 2023 (KR) 10-2023-0157310

(51) Int. Cl. H01L 29/417; H01L 23/528; H01L 29/06; H01L 29/08; H01L 29/423; H01L 29/775; H01L 29/786

(52) U.S. Cl. CPC H10D 30/6729; H01L 23/528; H01L 23/5283; H10D 30/43; H10D 30/6735; H10D 30/6757; H10D 62/121; H10D 62/151

(57) ABSTRACT

A semiconductor device is provided. The semiconductor device includes a first lower pattern extending in a first direction and including first and second sidewalls, which are opposite to each other in a second direction, and upper and lower surfaces, which are opposite to each other in a third direction, a channel separation structure extending in the first direction and contacting the first sidewall of the first lower pattern, a field insulating film contacting the second sidewall of the first lower pattern, first channel patterns disposed on an upper surface of the first lower pattern and including first sheet patterns, which are spaced apart from one another in the third direction, the first sheet patterns contacting the channel separation structure, first source/drain patterns contacting the first channel patterns and the channel separation structure, contact blocking patterns disposed on the first source/drain patterns and formed of an insulating material, the contact blocking patterns having upper surfaces on the same plane as an upper surface of the channel separation structure, first backside source/drain contacts disposed within the first lower pattern and connected to the first source/drain patterns and backside wiring lines disposed on the lower surface of the first lower pattern and connected to the first backside source/drain contacts.

### CROSS-REFERENCE TO RELATED APPLICATION

This application is based on and claims priority to Korean Patent Application No. 10-2023-0157310, filed on Nov. 14, 2023, in the Korean Intellectual Property Office, the contents of which are herein incorporated by reference in its entirety.

### BACKGROUND

### 1. Field

The present disclosure relates to a semiconductor device.

### 2. Description of the Related Art

As a scaling technique for increasing the density of integrated circuit devices, the concept of a multi-gate transistor has been proposed in which a silicon body in the form of a fin or nanowire is formed on a substrate and a gate is formed on the surface of the silicon body.

The multi-gate transistor takes advantage of its three-dimensional (3D) channel, allowing for easy scaling both up and down. Additionally, the multi-gate transistor offers improved control over the current without the need to increase the gate length. Furthermore, the multi-gate transistor effectively mitigates the short channel effect (SCE), which is the phenomenon where the electric potential of a channel region is affected by the drain voltage.

Meanwhile, with the decrease in the pitch size of semiconductor devices, there is a need for research on methods to reduce capacitance between contacts and secure electrical stability.

### SUMMARY

Provided is a semiconductor device capable of improving device performance and integration density.

According to an aspect of the disclosure, a semiconductor device includes: a first lower pattern extending in a first direction and including a first sidewall, a second sidewall, an upper surface and a lower surface, wherein the first and second sidewalls are opposite to one another in a second direction, and wherein the upper and lower surfaces are opposite to one another in a third direction; a channel separation structure extending in the first direction and contacting the first sidewall of the first lower pattern; a field insulating film contacting the second sidewall of the first lower pattern; a first channel pattern on the upper surface of the first lower pattern, the first channel pattern including a plurality of first sheet patterns spaced apart from one another in the third direction, wherein the plurality of first sheet patterns are in contact with the channel separation structure; a first source/drain pattern in contact with the first channel pattern and the channel separation structure; a contact blocking pattern on the first source/drain pattern, wherein the contact blocking pattern is formed of an insulating material, and wherein the contact blocking pattern includes an upper surface on a same plane as an upper surface of the channel separation structure; a first backside source/drain contact within the first lower pattern and connected to the first source/drain pattern; and a backside wiring line on the lower surface of the first lower pattern, wherein the backside wiring line is connected to the first backside source/drain contact.

According to an aspect of the disclosure, a semiconductor device includes: a first channel separation structure extending in a first direction; a second channel separation structure spaced apart from the first channel separation structure in a second direction and extending in the first direction; a first lower pattern between the first and second channel separation structures, contacting the first channel separation structure, and including a first upper surface and a first lower surface, wherein the first upper surface and the first lower surface are opposite to each other; a second lower pattern between the first and second channel separation structures, wherein the second lower pattern is in contact with the second channel separation structure, extends in the first direction, and includes a second upper surface and a second lower surface, wherein the first upper surface and the second lower surface are opposite to each other; a field insulating film between the first and second lower patterns; a first channel pattern on the first upper surface, the first channel pattern including a plurality of first sheet patterns spaced apart from one another in a third direction, wherein the plurality of first sheet patterns are in contact with the first channel separation structure; a second channel pattern on the second upper surface, the second channel pattern including a plurality of second sheet patterns spaced apart from one another in the third direction, wherein the plurality of second sheet patterns are in contact with the second channel separation structure; a first source/drain pattern in contact with the first channel pattern and the first channel separation structure; a second source/drain pattern in contact with the second channel pattern and the second channel separation structure; a source/drain separation structure between the first source/drain pattern and the second source/drain pattern, the source/drain separation structure including an upper surface on a same plane as an upper surface of the first channel separation structure; a contact blocking pattern on the first source/drain pattern, wherein the contact blocking pattern is formed of an insulating material, and wherein the contact blocking pattern includes an upper surface on the same plane as the upper surface of the first channel separation structure; a source/drain contact on and connected to the second source/drain pattern, wherein the source/drain contact includes an upper surface on a same plane as an upper surface of the second channel separation structure; a backside source/drain contact within the first lower pattern and connected to the first source/drain pattern; and a backside wiring line on the first and second lower surfaces, wherein the backside wiring line is connected to the backside source/drain contact.

According to an aspect of the disclosure, a semiconductor device includes: a lower pattern extending in a first direction and including an upper surface and a lower surface, wherein the upper and lower surfaces are opposite to each other in a second direction; a channel separation structure extending in the first direction and contacting the lower pattern; a channel pattern on the upper surface of the lower pattern, the channel pattern including a plurality of sheet patterns spaced apart from one another in the second direction, wherein the plurality of sheet patterns are in contact with the channel separation structure; a first source/drain pattern on the lower pattern and in contact with the channel pattern; a second source/drain pattern on the lower pattern, wherein the second source/drain pattern is in contact with the channel pattern and the channel separation structure and is spaced apart from the first source/drain pattern in the first direction; a gate structure between the first source/drain pattern and the second source/drain pattern, wherein the gate structure is on the lower pattern and is in contact with the channel separation structure; a contact blocking pattern on the first source/drain pattern, wherein the contact blocking pattern is formed of an insulating material, and wherein the contact blocking pattern includes an upper surface on a same plane as an upper surface of the channel separation structure; a source/drain contact on and connected to the second source/drain pattern, the source/drain contact including an upper surface on a same plane as the upper surface of the contact blocking pattern; a backside source/drain contact within the lower pattern and connected to the first source/drain pattern; and a backside wiring line on the lower surface of the lower pattern, wherein the backside wiring line is connected to the backside source/drain contact.

It should be noted that the effects of the present disclosure are not limited to those described above, and other effects of the present disclosure will be apparent from the following description.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail example embodiments thereof with reference to the attached drawings, in which:

FIG. 1 is a layout view of a semiconductor device according to one or more embodiments of the present disclosure;

FIGS. 2, 3, 4, and 5 are cross-sectional views taken along lines A-A, B-B, C-C, and D-D, respectively, of FIG. 1;

FIG. 6 is a diagram illustrating certain surfaces corresponding to certain sheet patterns according to one or more embodiments of the disclosure;

FIG. 7 is a plan view illustrating an example of part P of FIG. 1;

FIG. 8 is an enlarged cross-sectional view illustrating an example of part Q of FIG. 4;

FIG. 9 is an enlarged cross-sectional view illustrating an example of part S of FIG. 5;

FIG. 10 is a plan view illustrating another example of part P of FIG. 1;

FIGS. 11 and 12 are enlarged cross-sectional views illustrating examples of part S of FIG. 5;

FIG. 13 is a drawing illustrating a semiconductor device according to one or more embodiments of the present disclosure;

FIGS. 14 and 15 are drawings illustrating a semiconductor device according to one or more embodiments of the present disclosure;

FIGS. 16 and 17 are drawings illustrating a semiconductor device according to one or more embodiments;

FIGS. 18 and 19 are drawings illustrating a semiconductor device according to one or more embodiments of the present disclosure;

FIG. 20 is a drawing illustrating a semiconductor device according to one or more embodiments of the present disclosure;

FIGS. 21 and 22 are drawings illustrating a semiconductor device according to one or more embodiments of the present disclosure;

FIGS. 23 and 24 are drawings illustrating a semiconductor device according to one or more embodiments of the present disclosure; and

FIGS. 25 through 42 are diagrams illustrating intermediate steps of a method of fabricating a semiconductor device according to one or more embodiments of the present disclosure.

### DETAILED DESCRIPTION

It should be understood that the terms “first,” “second,” “third,” etc., used herein to describe various elements, components, regions, layers, and/or sections are employed for the purpose of distinguishing one element, component, region, layer, or section from another, but not for limiting. Therefore, a first element, component, region, layer, or section described below could also be referred to as a second element, component, region, layer, or section, without deviating from the essence and scope of the present disclosure.

In the following description, like reference numerals refer to like elements throughout the specification. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

Transistors including nanowires or nanosheets are depicted as examples of semiconductor devices according to one or more embodiments of the present disclosure, but the present disclosure is not limited thereto. The technological principles described herein are also applicable to two-dimensional (2D) material-based field-effect transistors (FETs) and their heterostructures.

Moreover, the semiconductor devices according to one or more embodiments of the present disclosure may encompass fin-type FETs (FinFETs), tunneling FETs, and three-dimensional (3D) transistors including channel regions featuring fin-shaped patterns. Additionally, the semiconductor devices according to one or more embodiments of the present disclosure may include other types of transistors, such as bipolar junction transistors, lateral double-diffused metal-oxide semiconductor (LDMOS) transistors, among others.

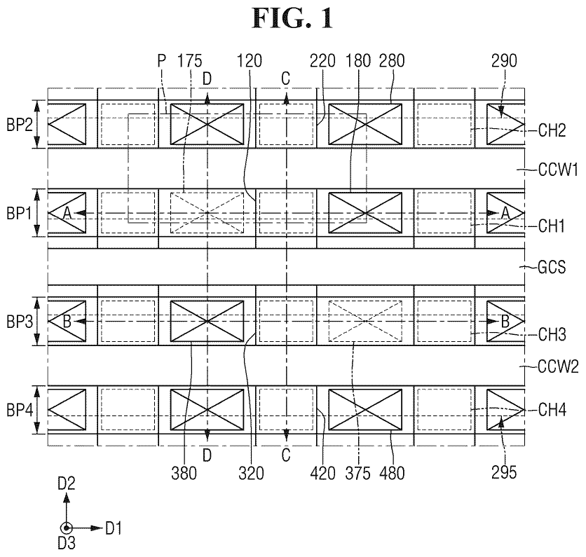

A semiconductor device according to one or more embodiments of the present disclosure will hereinafter be described with reference to FIGS. 1 through 9.

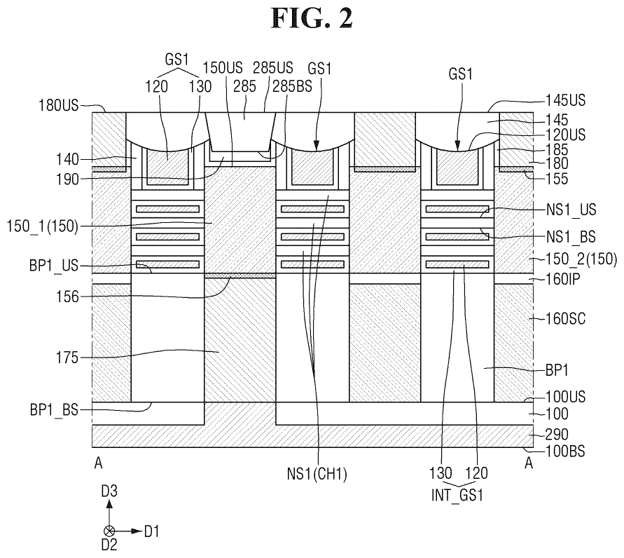

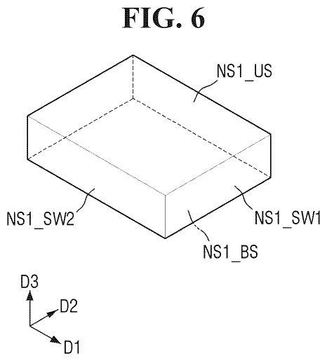

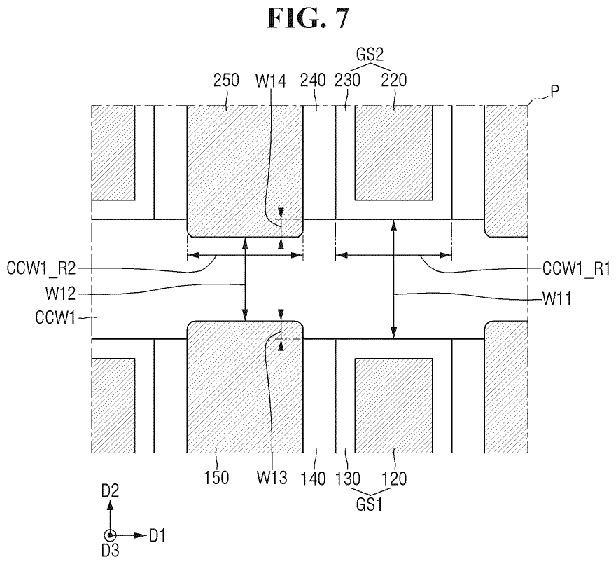

FIG. 1 is a layout view of a semiconductor device according to one or more embodiments of the present disclosure. FIGS. 2, 3, 4, and 5 are cross-sectional views taken along lines A-A, B-B, C-C, and D-D, respectively, of FIG. 1. FIG. 6 is a diagram illustrating certain surfaces corresponding to certain sheet patterns according to one or more embodiments of the disclosure. FIG. 7 is a plan view illustrating an example of part P of FIG.

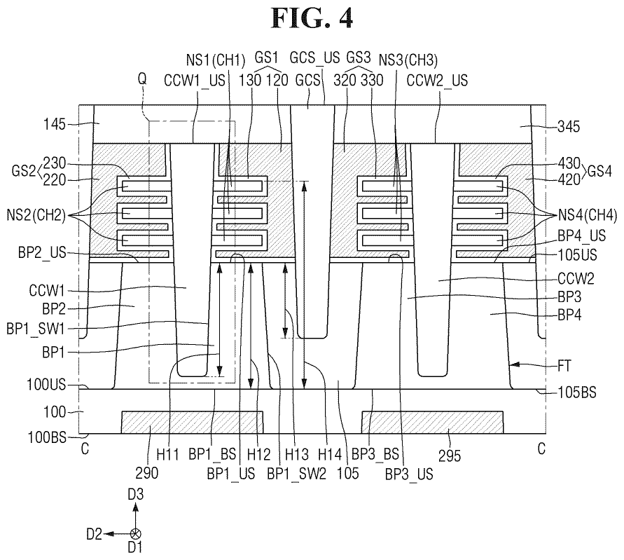

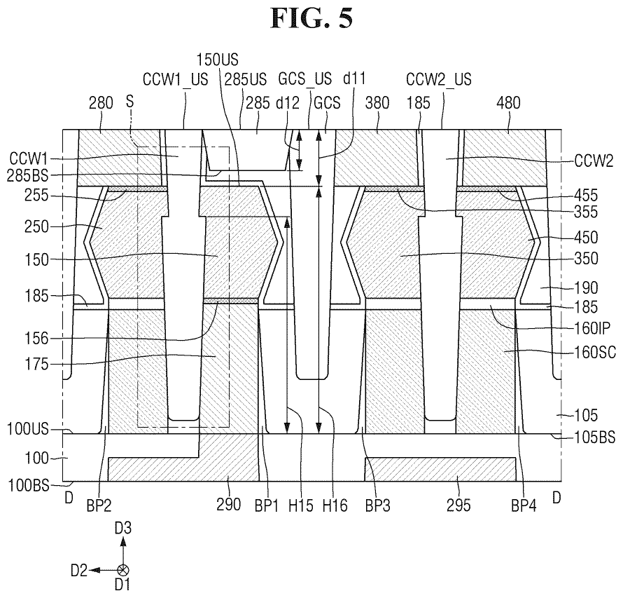

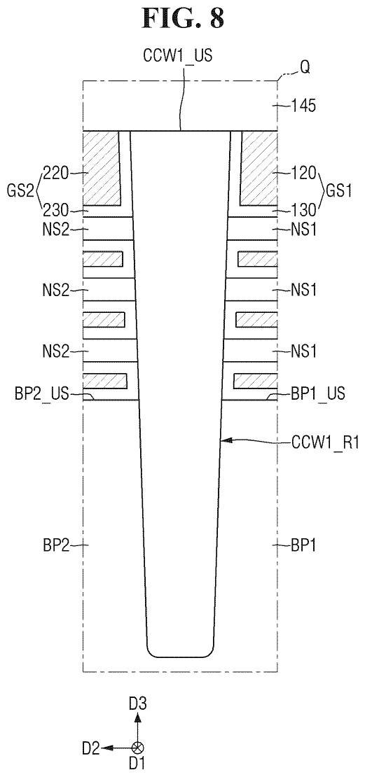

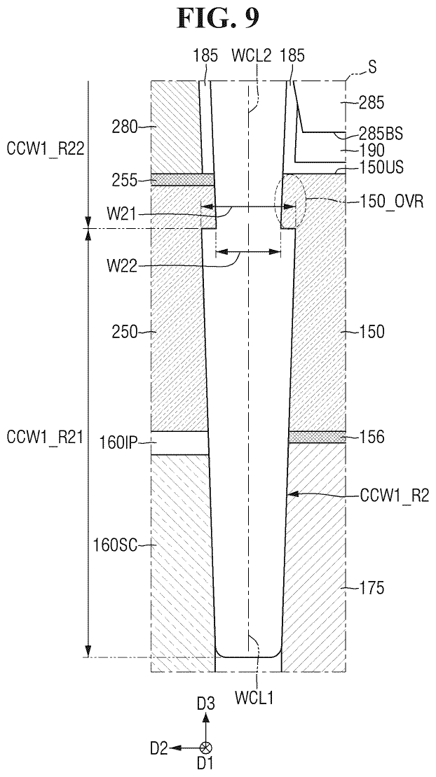

1. FIG. 8 is an enlarged cross-sectional view illustrating an example of part Q of FIG. 4. FIG. 9 is an enlarged cross-sectional view illustrating an example of part S of FIG. 5.

Specifically, FIG. 7 is a plan view cut between source/drain contacts (180 and 280) and uppermost sheet patterns (NS1 and NS2).

Referring to FIGS. 1 through 9, the semiconductor device according to one or more embodiments of the present disclosure may include a first lower pattern BP1, a second lower pattern BP2, a third lower pattern BP3, a fourth lower pattern BP4, first channel patterns CH1, second channel patterns CH2, third channel patterns CH3, fourth channel patterns CH4, a first channel separation structure CCW1, a second channel separation structure CCW2, first gate electrodes 120, second gate electrodes 220, third gate electrodes 320, fourth gate electrodes 420, first source/drain patterns 150, second source/drain patterns 250, third source/drain patterns 350, fourth source/drain patterns 450, contact blocking patterns 285, a gate separation structure GCS, first backside source/drain contacts 175, third backside source/drain contacts 375, first backside wiring lines 290, and second backside wiring lines 295.

The substrate 100 may have first and second surfaces 100US and 100BS, which are opposite to each other in a third direction D3. The first gate electrodes 120, the second gate electrodes 220, the third gate electrodes 320, the fourth gate electrodes 420, the first source/drain patterns 150, the second source/drain patterns 250, the third source/drain patterns 350, the fourth source/drain patterns 450, the first channel patterns CH1, the second channel patterns CH2, the third channel patterns CH3, and the fourth channel patterns CH4 may be disposed on the first surface 100US of the substrate 100, and the first surface 100US of the substrate 100 may be the upper surface of the substrate 100. The second surface 100BS of the substrate 100, which is opposite to the first surface 100US of the substrate 100, may be the lower surface of the substrate 100.

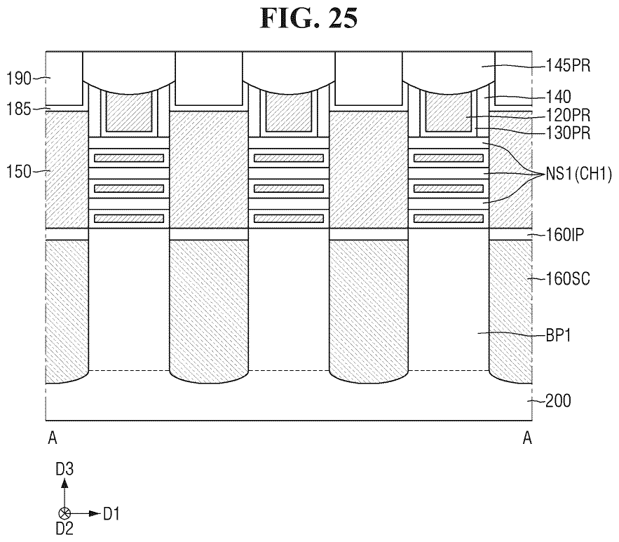

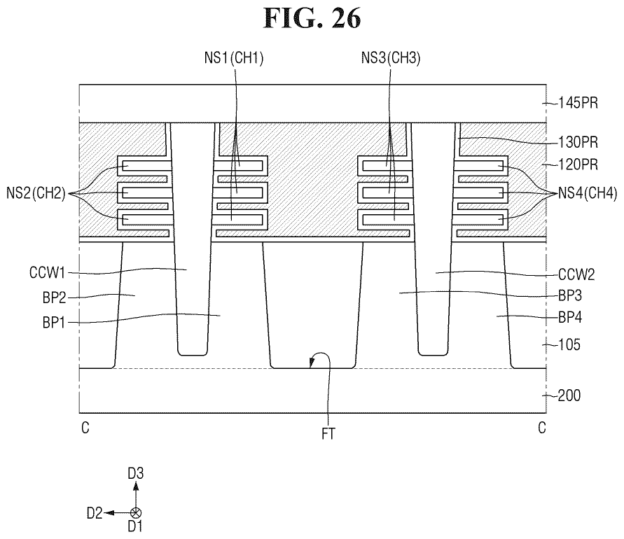

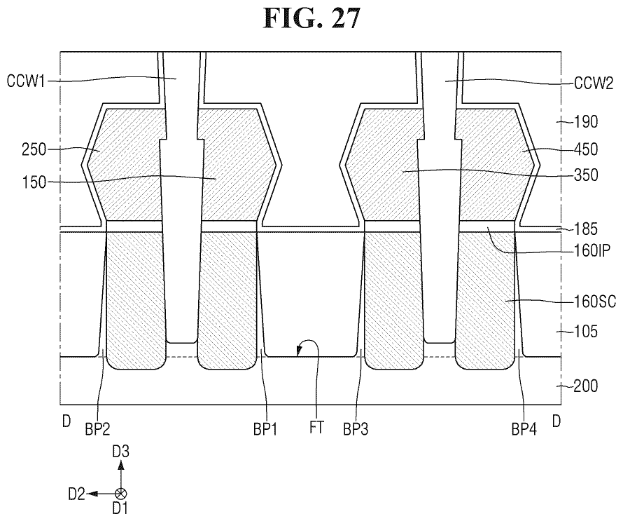

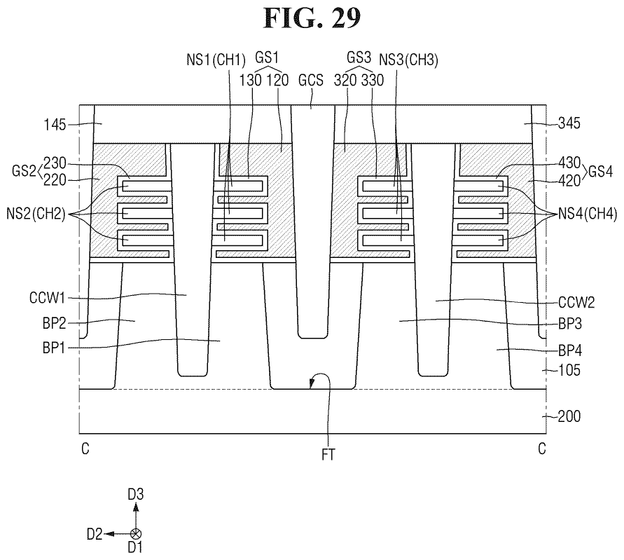

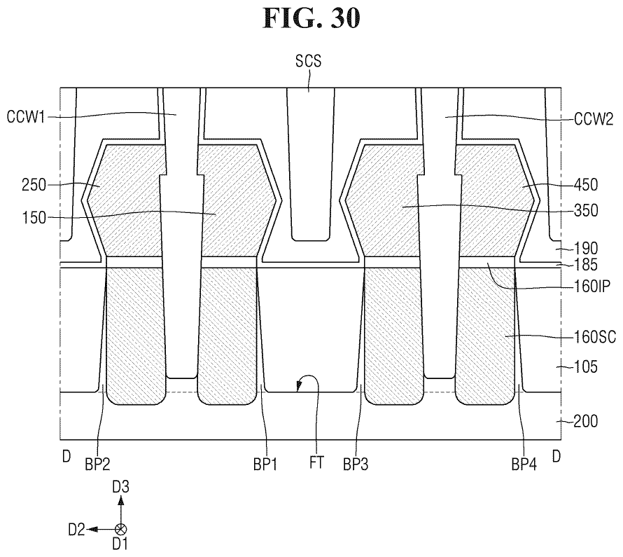

The substrate 100 may include an insulating material and may contain at least one of silicon oxide, silicon nitride, and a combination thereof. The substrate 100 may be formed by a deposition process after the removal of a support substrate 200, as illustrated in FIGS. 25 through 38.

The first and second lower patterns BP1 and BP2 may protrude from the substrate 100 in a third direction D3. The first and second lower patterns BP1 and BP2 may protrude from the first surface 100US of the substrate. The first and second lower patterns BP1 and BP2 may extend lengthwise in a first direction D1. The first and second lower patterns BP1 and BP2 may be spaced apart from each other in a second direction D2.

Similarly, the third and fourth lower patterns BP3 and BP4 may protrude from the substrate 100 in the third direction D3. The third and fourth lower patterns BP3 and BP4 may protrude from the first surface 100US of the substrate 100. The third and fourth lower patterns BP3 and BP4 may extend lengthwise in the first direction D1. The third and fourth lower patterns BP3 and BP4 may be spaced apart from each other in the second direction D2.

For example, the third direction D3 may correspond to a thickness of the substrate 100. The first and second directions D1 and D2 intersect the third direction D3. The first direction D1 intersects the second direction D2.

The first and third lower patterns BP1 and BP3 may be disposed between the second and fourth lower patterns BP2 and BP4. The first lower pattern BPI may be disposed between the second and third lower patterns BP2 and BP3. The first and third lower patterns BP1 and BP3 may be separated by a fin trench FT extending in the first direction D1.

The first lower pattern BP1 will hereinafter be described in further detail as an example. The first lower pattern BP1 may include first and second sidewalls BP1_SW1 and BP1_SW2, which are opposite to each other in the second direction D2. The first and second sidewalls BP1_SW1 and BP1_SW2 of the first lower pattern BP1 may extend in the first direction D1. The second sidewall BP1_SW2 of the first lower pattern BP1 may be defined by the fin trench FT. The first sidewall BP1_SW1 of the first lower pattern BP1 is not defined by the fin trench FT.

Similarly, each of the second, third, and fourth lower patterns BP2, BP3, and BP4 may include opposite first and second sidewalls in the second direction D2. For example, the second sidewall BP1_SW2 of the first lower pattern BP1 and the second sidewall of the third lower pattern BP3 may be defined by the fin trench FT so that the second sidewall BP1_SW2 of the first lower pattern may face the second sidewall of the third lower pattern BP3.

The first lower pattern BP1 may include upper and lower surfaces BP1_US and BP1_BS, which are opposite to each other in the third direction D3. The second lower pattern BP2 may include an upper surface BP2_US and a lower surface, which are opposite to each other in the third direction D3. The third lower pattern BP3 may include upper and lower surfaces BP3_US and BP3_BS, which are opposite to each other in the third direction. The fourth lower pattern BP4 may include upper and lower surfaces BP4_US and BP4_BS, which are opposite to each other in the third direction. The lower surface BP1_BS of the first lower pattern BP1, the lower surface of the second lower pattern BP2, the lower surface BP3_BS of the third lower pattern BP3, and the lower surface of the fourth lower pattern BP4 may face the first surface 100US of the substrate 100. The substrate 100 may be disposed on the lower surface BP1_BS of the first lower pattern BP1, the lower surface of the second lower pattern BP2, the lower surface BP3_BS of the third lower pattern BP3, and the lower surface of the fourth lower pattern BP4.

For example, the first, second, third, and fourth lower patterns BP1, BP2, BP3, and BP4 may contact the substrate 100. An inserted insulating capping layer may be disposed on the first surface 100US of the substrate 100. The inserted insulating capping layer may be disposed between the substrate 100 and the first lower pattern BP1 and between the substrate 100 and the second lower pattern BP2. The inserted insulating capping layer may also be disposed between the substrate 100 and the third lower pattern BP3, and between the substrate 100 and the fourth lower pattern BP4. The inserted insulating capping layer may include a different insulating material from the substrate 100.

The first and second lower patterns BP1 and BP2 may be disposed in an area where transistors of the same conductivity type are formed. The third and fourth patterns BP3 and BP4 may also be disposed in an area where transistors of the same conductivity type are formed. For example, the first lower pattern BP1 may be disposed in a P-type metal-oxide semiconductor (PMOS) formation area, and the third lower pattern BP3 may be disposed in an N-type metal-oxide semiconductor (NMOS) formation area. Alternatively, the first and third lower patterns BP1 and BP3 may be disposed in the PMOS formation area. Yet alternatively, the third lower patterns BP1 and BP3 may be disposed in the NMOS formation area.

Each of the first, second, third, and fourth lower patterns BP1, BP2, BP3, and BP4 may be formed by partially etching the support substrate 200 or may include an epitaxial layer grown from the support substrate 200. The first, second, third, and fourth lower patterns BP1, BP2, BP3, and BP4 may include an element semiconductor material, such as silicon (Si) or germanium (Ge). The first, second, third, and fourth lower patterns BP1, BP2, BP3, and BP4 may also include a compound semiconductor, such as a group IV-IV compound semiconductor or a group III-V compound semiconductor.

The group IV-IV compound semiconductor may be a binary or ternary compound containing at least two of carbon (C), Si, Ge, and tin (Sn), or a compound formed by doping the binary or ternary compound with a group IV element.

The group III-V compound semiconductor may be a binary, ternary, or quaternary compound formed by combining at least one group III element, such as aluminum Al, gallium (Ga), and indium (In), with a group V element, such as phosphorus (P), arsenic (As), or antimony (Sb).

The first and second lower patterns BP1 and BP2 may include the same material. The third and fourth lower patterns BP3 and BP4 may include the same material.

Field insulating films 105 may be disposed on the substrate 100. For example, the field insulating film 105 may be disposed on the first surface 100US of the substrate 100. The field insulating film 105 may at least partially fill the fin trench FT that separates the first and third lower patterns BP1 and BP3.

From a cross-sectional perspective, the first and second lower patterns BP1 and BP2 may be disposed between portions of the field insulating film 105 that are adjacent in the second direction D2, and the third and fourth lower patterns BP1 and BP2 may also be disposed between portions of the field insulating film 105 that are adjacent in the second direction D2.

The field insulating film 105 is not disposed on the upper surface BP1_US of the first lower pattern BP1, the upper surface BP2_US of the second lower pattern BP2, the upper surface BP3_US of the third lower pattern BP3, and the upper surface BP4_US of the fourth lower pattern BP4.

The field insulating film 105 may contact the second sidewall BP1_SW2 of the first lower pattern BP1 and the second sidewall of the third lower pattern BP3. For example, the field insulating film 105 may entirely cover the second sidewall BP1_SW2 of the first lower pattern BP1 and the second sidewall of the third lower pattern BP3. Alternatively, the field insulating film 105 may cover only part of the second sidewall BP1_SW2 of the first lower pattern BP1 and/or part of the second sidewall of the third lower pattern BP3.

The field insulating film 105 may include an upper surface 105US and a lower surface 105BS, which are opposite to each other in the third direction D3. The lower surface 105BS of the field insulating film 105 may face the substrate 100.

For example, the lower surface 105BS of the field insulating film 105 may contact the substrate 100. Alternatively, in a case where the inserted insulating capping layer is disposed between the substrate 100 and the first, second, third, and fourth lower patterns BP1, BP2, BP3, and BP4, the lower surface 105BS of the field insulating film may contact the inserted insulating capping layer.

The upper surface 105US of the field insulating film 105 is illustrated as being flat, but the present disclosure is not limited thereto. The field insulating film 105 may include, for example, an oxide film, a nitride film, an oxynitride film, or a combination thereof. The field insulating film 105 is illustrated as being a single film, but the present disclosure is not limited thereto.

A plurality of first channel patterns CH1 may be disposed on the first lower pattern BP1. The first channel patterns CH1 may overlap with the first lower pattern BP1 in the third direction D3. The first channel patterns CH1 may be aligned in the first direction D1.

A plurality of second channel patterns CH2 may be disposed on the second lower pattern BP2. The second channel patterns CH2 may overlap with the second lower pattern BP2 in the third direction D3. The second channel patterns CH2 may be aligned in the first direction D1. The second channel patterns CH2 may be disposed to correspond to the first channel patterns CH1. The first channel patterns CH1 and their corresponding second channel patterns CH2 may be spaced apart from one another in the second direction D2.

A plurality of third channel patterns CH3 may be disposed on the third lower pattern BP3. The third channel patterns CH3 may overlap with the third lower pattern BP3 in the third direction D3. The third channel patterns CH3 may be aligned in the first direction D1.

A plurality of fourth channel patterns CH4 may be disposed on the fourth lower pattern BP4. The fourth channel patterns CH4 may overlap with the fourth lower pattern BP4 in the third direction D3. The fourth channel patterns CH4 may be aligned in the first direction D1. The fourth channel patterns CH4 may be disposed to correspond to the third channel patterns CH3. The fourth channel patterns CH4 and their corresponding fourth channel patterns CH3 may be spaced apart from one another in the second direction D2.

The first channel patterns CH1, the second channel patterns CH2, the third channel patterns CH3, and the fourth channel patterns CH4 may each include a plurality of sheet patterns that are spaced apart from one another in the third direction D3. The first channel patterns CH1, the second channel patterns CH2, the third channel patterns CH3, and the fourth channel patterns CH4 are each illustrated as including three sheet patterns, but the present disclosure is not limited thereto.

Each of the first channel patterns CH1 may include a plurality of first sheet patterns NS1. The first sheet patterns NS1 may be disposed on the upper surface BP1_US of the first lower pattern BP1. The first sheet patterns NS1 may be arranged on the first lower pattern BP1 in the third direction D3. The first sheet patterns NS1 may be spaced apart from one another in the third direction D3. Each of the first sheet patterns NS1 may have an upper surface NS1_US and a lower surface NS1_BS, which are opposite to each other in the third direction D3. For example, the upper surface NS1_US of the uppermost first sheet pattern NS1 may correspond to the upper surface of the array of the first channel patterns CH1.

Each of the third sheet patterns CH3 may include a plurality of third sheet patterns NS3. The third sheet patterns NS3 may be disposed on the upper surface BP3_US of the third lower pattern BP3. The third sheet patterns NS3 may be arranged on the third lower pattern BP3 in the third direction D3. The third sheet patterns NS3 may be spaced apart from one another in the third direction D3. Each of the third sheet patterns NS3 may have an upper surface NS3_US and a lower surface NS3_BS, which are opposite to each other in the third direction D3.

Each of the second channel patterns CH2 may include a plurality of second sheet patterns NS2. The second sheet patterns NS2 may be disposed on the upper surface BP2_US of the second lower pattern BP2. The second sheet patterns NS2 may be spaced apart from one another in the third direction D3. Each of the fourth channel patterns CH4 may include a plurality of fourth sheet patterns NS4. The fourth sheet patterns NS4 may be disposed on the upper surface BP4_US of the fourth lower pattern BP4. The fourth sheet patterns NS4 may be spaced apart from one another in the third direction D3.

The first sheet patterns NS1 will hereinafter be described in further detail as an example. As shown in FIG. 6, each of the first sheet patterns NS1 may have first sidewalls NS1_SW1, which are opposite to each other in the first direction D1, and second sidewalls NS1_SW2, which are opposite to each other in the second direction D2. The upper surface NS1_US and the lower surface NS1_BS of each of the first sheet patterns NS1 may be connected by the first sidewalls NS1_SW1 and the second sidewalls NS1_SW2 of a corresponding first sheet pattern NS1. The first sidewalls NS1_SW1 of each of the first sheet patterns NS1 may be connected to and in contact with first source/drain patterns 150. The above description of the first sheet patterns NS1 may be directly applicable to the second sheet patterns NS2, the third sheet patterns NS3, and the fourth sheet patterns NS4.

The first sheet patterns NS1, the second sheet patterns NS2, the third sheet patterns NS3, and the fourth sheet patterns NS4 may include one of an element semiconductor material (e.g., Si or Ge), a group IV-IV compound semiconductor, and a group III-V compound semiconductor. The first sheet patterns NS1 and the second sheet patterns NS2 may include the same material as the first lower pattern BP1 or a different material from the first lower pattern BP1. The third sheet patterns NS3 and the fourth sheet patterns NS4 may include the same material as the third lower pattern BP3 or a different material from the third lower pattern BP3.

The first sheet patterns NS1, the second sheet patterns NS2, the third sheet patterns NS3, and the fourth sheet patterns NS4 may be Si lower patterns containing Si. The first sheet patterns NS1, the second sheet patterns NS2, the third sheet patterns NS3, and the fourth sheet patterns NS4 may be Si sheet patterns containing Si.

The first channel separation structure CCW1 may be disposed on the first surface 100US of the substrate 100. The first channel separation structure CCW1 may be disposed between the first and second lower patterns BP1 and BP2. The first channel separation structure CCW1 may extend in the first direction D1.

The first channel separation structure CCW1 may separate the first and second lower patterns BP1 and BP2. The first channel separation structure CCW1 separates the first channel patterns CH1 and the second channel patterns CH2. The first and second lower patterns BP1 and BP2 may cover portions of the sidewalls of the first channel separation structure CCW1. The sidewalls of the first channel separation structure CCW1 may extend in the first direction D1.

The first channel separation structure CCW1 may contact the first and second lower patterns BP1 and BP2. The first channel separation structure CCW1 may contact the first sidewall BP1_SW1 of the first lower pattern BP1 and the first sidewall of the second lower pattern BP2. The first sidewall BP1_SW1 of the first lower pattern BP1 faces the first sidewall of the second lower pattern BP2.

The first channel patterns CH1 and the second channel patterns CH2 contact the first channel separation structure CCW1. The first sheet patterns NS1 and the second sheet patterns NS2 contact the first channel separation structure CCW1. The first sheet patterns NS1 and the second sheet patterns NS2 may protrude in the second direction D2 from the sidewalls of the first channel separation structure CCW1. For example, one of the second sidewalls NS1_SW2 of each of the first sheet patterns NS1 may contact the first channel separation structure CCW1, and one of the second sidewalls of each of the second sheet pattern NS2 may contact the first channel separation structure CCW1.

The second channel separation structure CCW2 may be disposed on the first surface 100US of the substrate 100. The second channel separation structure CCW2 may be disposed between the third and fourth lower patterns BP3 and BP4. The second channel separation structure CCW2 may extend in the first direction D1. The second channel separation structure CCW2 is spaced apart from the first channel separation structure CCW1 in the second direction D2.

The second channel separation structure CCW2 may separate the third and fourth lower patterns BP3 and BP4. The second channel separation structure CCW2 separates the third channel patterns CH3 and the fourth channel patterns CH4. The third and fourth lower patterns BP3 and BP4 may cover portions of the sidewalls of the second channel separation structure CCW2. The sidewalls of the second channel separation structure CCW2 may extend in the first direction D1.

The second channel separation structure CCW2 may contact the third and fourth lower patterns BP3 and BP4. The second channel separation structure CCW2 may contact the first sidewall of the third lower pattern BP3 and the first sidewall of the fourth lower pattern BP4. The first sidewall of the third lower pattern BP3 faces the first sidewall of the fourth lower pattern BP4.

The third channel patterns CH3 and the fourth channel patterns CH4 contact the second channel separation structure CCW2. The third sheet patterns NS3 and the fourth sheet patterns NS4 contact the second channel separation structure CCW2. The third sheet patterns NS3 and the fourth sheet patterns NS4 may protrude in the second direction D2 from the sidewalls of the second channel separation structure CCW2. One of the second sidewalls of each of the third sheet patterns NS3 contacts the second channel separation structure CCW2. One of the second sidewalls of each of the fourth sheet patterns NS4 contacts the second channel separation structure CCW2.

The first and second channel separation structures CCW1 and CCW2 may include an insulating material. The first and second channel separation structures CCW1 and CCW2 may include at least one of, silicon nitride (SiN), silicon oxynitride (SiON), silicon oxide (SiO₂), silicon oxycarbonitride (SiOCN), silicon boron nitride (SiBN), silicon oxyboronitride (SiOBN), silicon oxycarbide (SiOC), aluminum oxide (AlO), and a combination thereof, but the present disclosure is not limited thereto. The first and second channel separation structures CCW1 and CCW2 are illustrated as being single films, but the present disclosure is not limited thereto. Since the first and second channel separation structures CCW1 and CCW2 are formed at the same time, the first and second channel separation structures CCW1 and CCW2 may include the same material.

The description of the second channel separation structure CCW2 may be substantially the same as that of the first channel separation structure CCW1, and thus, the description of the first channel separation structure CCW1 may be directly applicable to the second channel separation structure CCW2. The shape of the first channel separation structure CCW1 will be described later.

A depth H11 from the upper surface BP1_US of the first lower pattern BP1 to a lowermost portion of the first channel separation structure CCW1 may be less than a depth H12 from the upper surface BP1_US of the first lower pattern BP1 to the lower surface 105BS of the field insulating film 105.

The gate separation structure GCS may be disposed on the first surface 100US of the substrate 100. The gate separation structure GCS may extend in the first direction D1. The gate separation structure GCS may be disposed on the field insulating film 105. Portions of the gate separation structure GCS may be disposed within upper interlayer insulating films 190.

The gate separation structure GCS may contact the field insulating film 105. The gate separation structure GCS may protrude in the third direction D3 beyond the upper surface 105US of the field insulating film 105. For example, part of the gate separation structure GCS may be embedded into the field insulating film 105.

The gate separation structure GCS may be disposed between the first and second channel separation structures CCW1 and CCW2. The first channel patterns CH1, the second channel patterns CH2, the third channel patterns CH3, and the fourth channel patterns CH4 may be disposed between the gate separation structure GCS and the first and second channel separation structures CCW1 and CCW2.

For example, the depth H11 from the upper surface BP1_US of the first lower pattern BP1 to the lowermost portion of the first channel separation structure CCW1 may be greater than a depth H13 from the upper surface BP1_US of the first lower pattern BP1 to the lowermost portion of the gate separation structure GCS, but the present disclosure is not limited thereto.

The gate separation structure GCS contains an insulating material. For example, the gate separation structure GCS may include at least one of SiN, SiON, SiO2, SiOCN, SiBN, SiOBN, SiOC, AlO, and a combination thereof. The gate separation structure GCS is illustrated as being a single layer, but the present disclosure is not limited thereto.

The first gate structures GS1, the second gate structures GS2, the third gate structures GS3, and the fourth gate structures GS4 may be disposed on the first surface 100US of the substrate 100. The first gate structures GS1, the second gate structures GS2, the third gate structures GS3, and the fourth gate structures GS4 may contact the upper surface 105US of the field insulating film 105.

The first gate structures GS1 may be disposed between the first channel separation structure CCW1 and the gate separation structure GCS. The first gate structures GS1 may contact the first channel separation structure CCW1 and the gate separation structure GCS. The first gate structures GS1 may be adjacent to one another in the first direction D1.

The first gate structures GS1 may be disposed on the first lower pattern BP1. For example, the first gate structures GS1 may contact the upper surface BP1_US of the first lower pattern BP1. The first channel patterns CH1 may be disposed between the first gate structure GS1 and the first channel separation structure CCW1. The first sheet patterns NS1 may be disposed between the first gate structures GS1 and the first channel separation structure CCW1. As the first sheet patterns NS1 are in contact with the first channel separation structure CCW1, the first gate structures GS1 may not surround the first sheet patterns NS1 from a cross-sectional perspective.

The first gate structures GS1 may include the first gate electrodes 120 and the first gate insulating films 130. The first gate electrodes 120 may be disposed on the first lower pattern BP1. The first gate insulating films 130 may be disposed between the first gate electrodes 120 and the first channel patterns CH1. For example, the first gate insulating films 130 may be disposed between the first gate electrodes 120 and the first sheet patterns NS1.

The first gate insulating films 130 may extend along the upper surface 105US of the field insulating film 105 and the upper surface BP1_US of the first lower pattern BP1. The first gate insulating films 130 may contact the upper surface 105US of the field insulating film 105 and the upper surface BP1_US of the first lower pattern BP1. From a cross-sectional perspective, as illustrated in FIG. 4, the first gate insulating films 130 may extend along the sidewalls of the first channel separation structure CCW1. The first gate electrodes 120 may not contact the sidewalls of the first channel separation structure CCW1. The first gate insulating films 130 do not extend along the sidewalls of the gate separation structure GCS. The first gate electrodes 120 may contact the sidewalls of the gate separation structure GCS. The first gate insulating films 130 may be disposed along portions of the peripheries of the first sheet patterns NS1.

The first gate structures GS1 may include first inner gate structures INT_GS1. The first inner gate structures INT_GS1 may be disposed between the first lower pattern BP1 and the first sheet patterns NS1 and between the first sheet patterns NS1 that are adjacent to one another in the third direction D3. The first inner gate structures INT_GS1 contact the upper surface BP1_US of the first lower pattern BP1, the upper surfaces NS1_US of the first sheet patterns NS1, and the lower surfaces NS1_BS of the first sheet patterns NS1. The first gate insulating films 130 included in the first inner gate structures INT_GS1 may contact the first source/drain patterns 150 that will be described later.

The description of the second gate structures GS2, the third gate structures GS3, and the fourth gate structures GS4 may be substantially the same as that of the first gate structures GS1, and thus, the second gate structures GS2, the third gate structures GS3, and the fourth gate structures GS4 will hereinafter be described only briefly.

The second gate structures GS2 may be disposed between the first channel separation structure CCW1 and the gate separation structure GCS. The second gate structures GS2 may contact the first channel separation structure CCW1 and the gate separation structure GCS. The first channel separation structure CCW1 may be disposed between the first gate structures GS1 and the second gate structures GS2. The second gate structures GS2 may be adjacent to one another in the first direction D1. The second gate structures GS2 may be spaced apart from the first gate structure GS1 in the second direction D2.

The second gate structures GS2 may be disposed on the second lower pattern BP2. For example, the second gate structures GS2 may contact the upper surface BP2_US of the second lower pattern BP2. The second channel patterns CH2 may be disposed between the second gate structures GS2 and the first channel separation structure CCW1. The second sheet patterns NS2 may be disposed between the second gate structures GS2 and the first channel separation structure CCW1. The second gate structures GS2 may include the second gate electrodes 220 and the second gate insulating films 230. The second gate structures GS2 may include second inner gate structures, which may be disposed between the second lower pattern BP2 and the second sheet patterns NS2, and between the second sheet patterns NS2 that are adjacent to one another in the third direction D3.

The third gate structures GS3 may be disposed between the second channel separation structure CCW2 and the gate separation structure GCS. The third gate structures GS3 may contact the second channel separation structure CCW2 and the gate separation structure GCS. The third gate structures GS3 may be adjacent to one another in the first direction D1. The third gate structures GS3 may be spaced apart from the first gate structures GS1 in the second direction D2.

The third gate structures GS3 may be disposed on the third lower pattern BP3. For example, the third gate structures GS3 may contact the upper surface BP3_US of the third lower pattern BP3. The third channel patterns CH3 may be disposed between the third gate structures GS3 and the second channel separation structure CCW2. The third sheet patterns NS3 may be disposed between the third gate structures GS3 and the second channel separation structure CCW2. The third gate structures GS3 may include the third gate electrodes 320 and the third gate insulating films 330. The third gate structures GS3 may include third inner gate structures INT_GS3, which may be disposed between the third lower pattern BP3 and the third sheet patterns NS3, and between the third sheet patterns NS3 that are adjacent to one another in the third direction D3. The third gate insulating films 330 included in the third inner gate structures INT_GS3 may contact the third source/drain patterns 350 that will be described later.

The fourth gate structures GS4 may be disposed between the second channel separation structure CCW2 and the gate separation structure GCS. The fourth gate structures GS4 may contact the second channel separation structure CCW2 and the gate separation structure GCS. The second channel separation structure CCW2 may be disposed between the third gate structures GS3 and the fourth gate structures GS4. The fourth gate structures GS4 may be adjacent to one another in the first direction D1. The fourth gate structures GS4 may be spaced apart from the third gate structures GS3 in the second direction D2.

The fourth gate structures GS4 may be disposed on the fourth lower pattern BP4. For example, the fourth gate structures GS4 may contact the upper surface BP4_US of the fourth lower pattern BP4. The fourth channel patterns CH4 may be disposed between the fourth gate structures GS4 and the second channel separation structure CCW2. The fourth sheet patterns NS4 may be disposed between the fourth gate structures GS4 and the second channel separation structure CCW2. The fourth gate structures GS4 may include the fourth gate electrodes 420 and the fourth gate insulating films 430. The fourth gate structures GS4 may include fourth inner gate structures, which may be disposed between the fourth lower pattern BP4 and the fourth sheet patterns NS4, and between the fourth sheet patterns NS4 that are adjacent to one another in the third direction D3.

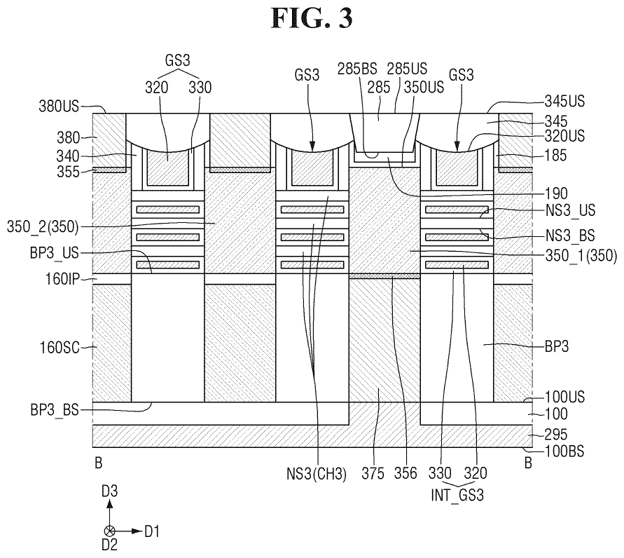

In a cross-sectional view such as FIGS. 2 and 3, upper surfaces 120US of the first gate electrodes 120 and upper surfaces 320US of the third gate electrodes 320 are illustrated as being concave surfaces, however the present disclosure is not limited thereto. Alternatively, the upper surfaces 120US of the first gate electrodes 120 and the upper surfaces 320US of the third gate electrodes 320 may also be flat.

In a cross-sectional view such as FIG. 4, the upper surfaces 120US of the first gate electrodes 120 and the upper surfaces of the second gate electrodes 220 may be flat, and the upper surfaces 320US of the third gate electrodes 320 and the upper surfaces of the fourth gate electrodes 420 may be flat.

The first gate electrodes 120, the second gate electrodes 220, the third gate electrodes 320, and the fourth gate electrodes 420 may include at least one of a metal, a metal alloy, a conductive metal nitride, a metal silicide, a doped semiconductor material, a conductive metal oxide, and a conductive metal oxynitride. The first gate electrodes 120, the second gate electrodes 220, the third gate electrodes 320, and the fourth gate electrodes 420 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAICN), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium Nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but the present disclosure is not limited thereto. Here, the conductive metal oxide and the conductive metal oxynitride may encompass oxidized forms of the above-mentioned materials, but the present disclosure is not limited thereto.

The first gate insulating films 130, the second gate insulating films 230, the third gate insulating films 330, and the fourth gate insulating films 430 may include silicon oxide, silicon oxynitride, silicon nitride, or a high-k material with a greater dielectric constant than silicon oxide. The high-k material may include at least one of, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The first gate insulating films 130, the second gate insulating films 230, the third gate insulating films 330, and the fourth gate insulating films 430 are illustrated as being single films, but the present disclosure is not limited thereto. Alternatively, the first gate insulating films 130, the second gate insulating films 230, the third gate insulating films 330, and the fourth gate insulating films 430 may include stacks of multiple films. For example, the first gate insulating films 130 may include interfacial layers, which may be disposed between the first channel patterns CH1 and the first gate electrodes 120, and high-k insulating films. For example, the interfacial films may not be formed along the profile of the upper surface 105US of the field insulating film 105.

The semiconductor device according to one or more embodiments of the present disclosure may include a negative capacitance (NC) field-effect transistor (FET) using a negative capacitor. For example, the first gate insulating films 130, the second gate insulating films 230, the third gate insulating films 330, and the fourth gate insulating films 430 may each include a ferroelectric material film having ferroelectric properties and a paraelectric material film having paraelectric properties.

The ferroelectric material film may have a negative capacitance, and the paraelectric material film may have a positive capacitance. For example, if two or more capacitors are connected in series and have positive capacitance, the total capacitance of the two or more capacitors may be lower than the capacitance of each of the two or more capacitors. On the contrary, if at least one of the two or more capacitors has negative capacitance, the total capacitance of the two or more capacitors may have a positive value and may be greater than the absolute value of the capacitance of each of the two or more capacitors.

If the ferroelectric material film having a negative capacitance and the paraelectric material film having a positive capacitance are connected in series, the total capacitance of the ferroelectric material film and the paraelectric material film may increase. Accordingly, a transistor having the ferroelectric material film can have a sub-threshold swing (SS) of less than 60 mV/decade at room temperature.

The ferroelectric material film may have ferroelectric properties. The ferroelectric material film may include at least one of, for example, hafnium oxide, hafnium zirconium oxide, barium strontium titanium oxide, barium titanium oxide, and lead zirconium titanium oxide. For example, the hafnium zirconium oxide may be a material obtained by doping hafnium oxide with zirconium (Zr). In another example, the hafnium zirconium oxide may be a compound of hafnium (Hf), Zr, and oxygen (O).

The ferroelectric material film may further include a dopant. For example, the dopant may include at least one of Al, Ti, Nb, lanthanum (La), yttrium (Y), magnesium (Mg), Si, calcium (Ca), cerium (Ce), dysprosium (Dy), erbium (Er), gadolinium (Gd), Ge, scandium (Sc), strontium (Sr), and Sn. The type of dopant may vary depending on the type of material of the ferroelectric material film.

If the ferroelectric material film includes hafnium oxide, the dopant of the ferroelectric material film may include at least one of, for example, Gd, Si, Zr, Al, and Y.

If the dopant of the ferroelectric material film is Al, the ferroelectric material film may include about 3 atomic % (“at %”) to about 8 at % of Al. Here, the ratio of the dopant in the ferroelectric material film may refer to the ratio of the sum of the amounts of Hf and Al to the amount of Al in the ferroelectric material film.

If the dopant of the ferroelectric material film is Si, the ferroelectric material film may include about 2 at % to about 10 at % of Si. If the dopant of the ferroelectric material film is Y, the ferroelectric material film may include about 2 at % to about 10 at % of Y. If the dopant of the ferroelectric material film is Gd, the ferroelectric material film may include about 1 at % to about 7 at % of Gd. If the dopant of the ferroelectric material film is Zr, the ferroelectric material film may include about 50 at % to about 80 at % of Zr.

The paraelectric material film may include paraelectric properties. The paraelectric material film may include at least one of, for example, silicon oxide and a high-k metal oxide. The high-k metal oxide may include at least one of, for example, hafnium oxide, zirconium oxide, and aluminum oxide, but the present disclosure is not limited thereto.

The ferroelectric material film and the paraelectric material film may include the same material. The ferroelectric material film may have ferroelectric properties, but the paraelectric material film may not have ferroelectric properties. For example, if the ferroelectric material film and the paraelectric material film include hafnium oxide, the hafnium oxide included in the ferroelectric material film may have a different crystalline structure from the hafnium oxide included in the paraelectric material film.

The ferroelectric material film may be thick enough to exhibit ferroelectric properties. The ferroelectric material film may have a thickness of, for example, about 0.5 nm to about 10 nm, but the present disclosure is not limited thereto. A critical thickness that can exhibit ferroelectric properties may vary depending on the type of ferroelectric material, and thus, the thickness of the ferroelectric material film may vary depending on the type of ferroelectric material included in the ferroelectric material film.

For example, the first gate insulating films 130, the second gate insulating films 230, the third gate insulating films 330, and the fourth gate insulating films 430 may each include one ferroelectric material film. In another example, the first gate insulating films 130, the second gate insulating films 230, the third gate insulating films 330, and the fourth gate insulating films 430 may each include a plurality of ferroelectric material films that are spaced apart from one another. The first gate insulating films 130, the second gate insulating films 230, the third gate insulating films 330, and the fourth gate insulating films 430 may each have a structure in which a plurality of ferroelectric material films and a plurality of paraelectric material films are alternately stacked.

First gate spacers 140 may be disposed on the sidewalls of the first gate structures GS1. Second gate spacers 240 may be disposed on the sidewalls of the second gate structures GS2. Third gate spacers 340 may be disposed on the sidewalls of the third gate structures GS3. Fourth gate spacers may be disposed on the sidewalls of the fourth gate structures GS4.

For example, the first gate spacers 140 may not be disposed between the first lower pattern BP1 and the first sheet patterns NS1, and between the first sheet patterns NS1 that are adjacent to one another in the third direction D3, and the third gate spacers 340 may not be disposed between the third lower pattern BP3 and the third sheet patterns NS3, and between the third sheet patterns NS3 that are adjacent to one another in the third direction D3.

The first gate spacers 140, the second gate spacers 240, and the third gate spacers 340 may include at least one of SiN, SiON, SiO², SiOCN, SiBN, SiOBN, SiOC, and a combination thereof. The first gate spacers 140, the second gate spacers 240, and the third gate spacers 340 are illustrated as being single layers, but the present disclosure is not limited thereto.

First gate capping patterns 145 may be disposed on the first gate structures GS1 and the second gate structures GS2. The first gate capping patterns 145 may be disposed on the upper surfaces 120US of the first gate electrodes and 220 and the upper surfaces of the second gate electrodes 220. Upper surfaces 145US of the first gate capping patterns 145 may be on the same plane as an upper surface GCS_US of the gate separation structure GCS.

Second gate capping patterns 345 may be disposed on the third gate structures

GS3 and the fourth gate structures GS4. The second gate capping patterns 345 may be disposed on the upper surfaces 320US of the third gate electrodes and 420 of the fourth gate electrodes. The upper surface 345US of the second gate capping patterns 345 may be on the same plane as the upper surface GCS_US of the gate separation structure GCS.

In a cross-sectional view such as FIG. 4, the first gate capping patterns 145 may be disposed on the first channel separation structure CCW1. The first gate capping patterns 145 may be disposed on an upper surface CCW1_US of the first channel separation structure CCW1. The second gate capping patterns 345 may be disposed on the second channel separation structure CCW2. The second gate capping patterns 345 may be disposed on an upper surface CCW2_US of the second channel separation structure CCW2. The upper surface CCW1_US of the first channel separation structure CCW1 may be lower than the upper surface GCS_US of the gate separation structure GCS based on the lower surface 105BS of the field insulating film 105. The upper surface CCW2_US of the second channel separation structure CCW2 may be lower than the upper surface GCS_US of the gate separation structure GCS based on the lower surface 105BS of the field insulating film 105.

The first gate capping patterns 145 and the second gate capping patterns 345 may include at least one of SiN, SiON, SiCN, SiOCN, and a combination thereof.

The first source/drain patterns 150 may be disposed on the first lower pattern BP1. The first source/drain patterns 150 may be disposed adjacent to the first gate structure GS1 in the first direction D1. The first source/drain patterns 150 may be disposed between the first channel separation structure CCW1 and the gate separation structure GCS.

The first source/drain patterns 150 are connected to the first channel pattern CH1. The first source/drain patterns 150 may contact the first channel patterns CH1. The first source/drain patterns 150 may contact the first sheet patterns NS1. For example, the first source/drain patterns 150 may contact the first inner gate structures INT_GS1.

The first source/drain patterns 150 may include first lower connection semiconductor patterns 150_1 and first upper connection semiconductor patterns 150_2. The first lower connection semiconductor patterns 150_1 may be connected to the first backside source/drain contacts 175 and may not be connected to first source/drain contacts 180. The first upper connection semiconductor patterns 150_2 may be connected to the first source/drain contacts 180 and may not be connected to the first backside source/drain contacts 175.

The second source/drain patterns 250 may be disposed on the second lower pattern BP2. The second source/drain patterns 250 may be disposed adjacent to the second gate structures GS2 in the first direction D1. The second source/drain patterns 250 may be disposed between the first channel separation structure CCW1 and the gate separation structure GCS.

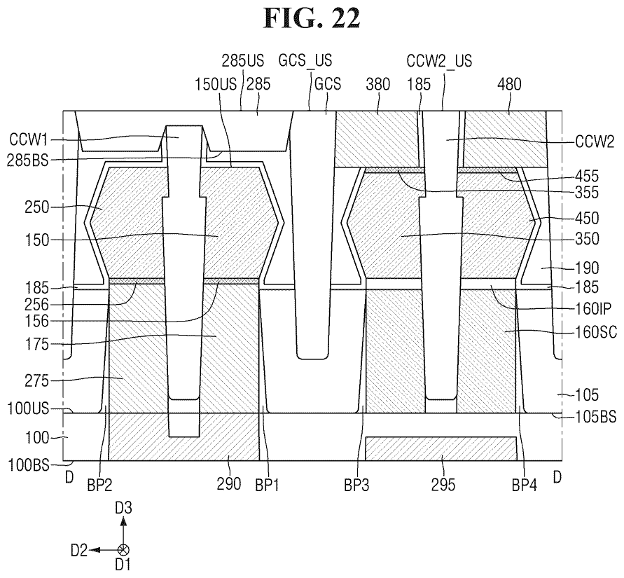

The second source/drain patterns 250 are connected to the second channel patterns CH2. The second source/drain patterns 250 may contact the second channel patterns CH2. The second source/drain patterns 250, like the first source/drain patterns 150, may include second upper connection semiconductor patterns, which are connected to second source/drain contacts 280, and second lower connection semiconductor patterns, which are connected to second backside source/drain contacts 275 of FIG. 22.

The third source/drain patterns 350 may be disposed on the third lower pattern BP3. The third source/drain patterns 350 may be disposed adjacent to the third gate structures GS3 in the first direction D1. The third source/drain patterns 350 may be disposed between the second channel separation structure CCW2 and the gate separation structure GCS.

The third source/drain patterns 350 are connected to the third channel patterns CH3. The third source/drain patterns 350 may contact the third channel patterns CH3. The third source/drain patterns 350 may contact the third sheet patterns NS3. For example, the third source/drain patterns 350 may contact the third inner gate structures INT_GS3.

The third source/drain patterns 350 may include third lower connection semiconductor patterns 350_1 and third upper connection semiconductor patterns 350_2. The third lower connection semiconductor patterns 350_1 may be connected to the third backside source/drain contacts 375 and may not be connected to third source/drain contacts 380. The third upper connection semiconductor patterns 350_2 may be connected to the third source/drain contacts 380 and may not be connected to the third backside source/drain contacts 375.

The fourth source/drain patterns 450 may be disposed on the fourth lower pattern BP4. The fourth source/drain patterns 450 may be disposed adjacent to the fourth gate structures GS4 in the first direction D1. The fourth source/drain patterns 450 may be disposed between the second channel separation structure CCW2 and the gate separation structure GCS.

The fourth source/drain patterns 450 are connected to the fourth channel patterns CH4. The fourth source/drain patterns 450 may contact the fourth channel patterns CH4. Similarly to the third source/drain patterns 350, the fourth source/drain patterns 450 may include fourth upper connection semiconductor patterns connected to fourth source/drain contacts 480, and fourth lower connection semiconductor patterns connected to fourth backside source/drain contacts.

The first channel separation structure CCW1 may be disposed between the first source/drain patterns 150 and the second source/drain patterns 250. The first source/drain patterns 150 and the second source/drain patterns 250 may be spaced apart from one another in the second direction D2.

The first source/drain patterns 150 and the second source/drain patterns 250 may contact the first channel separation structure CCW1. For example, the first source/drain patterns 150 and the second source/drain patterns 250 may contact the sidewalls of the first channel separation structure CCW1.

For example, portions of the first source/drain patterns 150 may overlap with the first channel separation structure CCW1 in the third direction D3. The first source/drain patterns 150 may include overlapping portions 150_OVR that overlap with the first channel separation structure CCW1 in the third direction D3. Portions of the first source/drain patterns 150 may be disposed over the first channel separation structure CCW1. Portions of the second source/drain patterns 250 may overlap with the first channel separation structure CCW1 in the third direction D3. Portions of the second source/drain patterns 250 may be disposed over the first channel separation structure CCW1.

The second channel separation structure CCW2 may be disposed between the third source/drain patterns 350 and the fourth source/drain patterns 450. The third source/drain patterns 350 and the fourth source/drain patterns 450 may be spaced apart from one another in the second direction D2.

The third source/drain patterns 350 and the fourth source/drain patterns 450 may contact the second channel separation structure CCW2. For example, the third source/drain patterns 350 and the fourth source/drain patterns 450 may contact the sidewalls of the second channel separation structure CCW2.

For example, portions of the third source/drain patterns 350 and portions of the fourth source/drain patterns 450 may overlap with the second channel separation structure CCW2 in the third direction D3. Portions of the third source/drain patterns 350 and portions of the fourth source/drain patterns 450 may be disposed over the second channel separation structure CCW2.

The first source/drain patterns 150, the second source/drain patterns 250, the third source/drain patterns 350, and the fourth source/drain patterns 450 may be disposed on the first surface 100US of the substrate 100. The first source/drain patterns 150 may be included in the source/drain of a transistor using the first sheet pattern NS1 as a channel region. The second source/drain patterns 250 may be included in the source/drain of a transistor using the second sheet pattern NS2 as a channel region. The third source/drain patterns 350 may be included in the source/drain of a transistor using the third sheet pattern NS3 as a channel region. The fourth source/drain patterns 450 may be included in the source/drain of a transistor using the fourth sheet pattern NS4 as a channel region.

The first source/drain patterns 150, the second source/drain patterns 250, the third source/drain patterns 350, and the fourth source/drain patterns 450 may include epitaxial patterns. The first source/drain patterns 150, the second source/drain patterns 250, the third source/drain patterns 350, and the fourth source/drain patterns 450 may be semiconductor patterns containing a semiconductor material.

The first source/drain patterns 150 and the second source/drain patterns 250 may include a dopant of the same conductivity type. The first source/drain patterns 150 and the second source/drain patterns 250 may include either a p-type dopant or an n-type dopant. The third source/drain patterns 350 and the fourth source/drain patterns 450 may include a dopant of the same conductivity type. The third source/drain patterns 350 and the fourth source/drain patterns 450 may include either the p-type dopant or the n-type dopant. The p-type dopant may include at least one of boron (B) and Ga, but the present disclosure is not limited thereto. The n-type dopant may include at least one of P, As, Sb, and bismuth (Bi), but the present disclosure is not limited thereto.

A height H14 from the lower surface 105BS of the field insulating film 105 to the upper surfaces of the first channel patterns CH1 is less than a height H16 from the lower surface 105BS of the field insulating film 105 to uppermost portions of the first source/drain patterns 150. For example, the upper surfaces 150US of the first source/drain patterns 150 include the uppermost portions of the first source/drain patterns 150. The uppermost portions of the first source/drain patterns 150 may be the furthest portions of the first source/drain patterns 150 from the lower surface 105BS of the field insulating film 105. The height of the upper surfaces 150US of the first source/drain patterns 150 may be measured in the first source/drain patterns 150 where first contact silicide films 155 are not formed.

Sacrificial semiconductor patterns 160SC may be disposed within the first, second, third, and fourth lower patterns BP1, BP2, BP3, and BP4. The sacrificial semiconductor patterns 160SC may be disposed between the first, second, third, and fourth lower patterns BP1, BP2, BP3, and BP4 and the substrate 100.

The sacrificial semiconductor patterns 160SC may overlap with the first source/drain patterns 150, the second source/drain patterns 250, the third source/drain patterns 350, and the fourth source/drain patterns 450 in the third direction D3. The first source/drain patterns 150, the second source/drain patterns 250, the third source/drain patterns 350, and the fourth source/drain patterns 450 may be disposed on the sacrificial semiconductor patterns 160SC. The sacrificial semiconductor patterns 160SC may be disposed below the first upper connection semiconductor patterns 150_2, the second upper connection semiconductor patterns, the third upper connection semiconductor patterns 350_2, and the fourth upper connection semiconductor patterns.

The sacrificial semiconductor patterns 160SC will hereinafter be described, taking those within the first lower pattern BP1 as an example. The sacrificial semiconductor patterns 160SC may extend to the lower surface BP1_BS of the first lower pattern BP1. If the first lower pattern BP1 contacts the first surface 100US of the substrate 100, the sacrificial semiconductor patterns 160SC may contact the substrate 100. Alternatively, lowermost portions of the sacrificial semiconductor patterns 160SC may not extend to the lower surface BP1_BS of the first lower pattern based on the first surface 100US of the substrate 100. Portions of the first lower pattern BP1 may be disposed between the substrate 100 and the sacrificial semiconductor patterns 160SC.

The sacrificial semiconductor patterns 160SC may include a material with an etch selectivity with respect to the first, second, third, and fourth lower patterns BP1, BP2, BP3, and BP4. If the first, second, third, and fourth lower patterns BP1, BP2, BP3, and BP4 are Si patterns, the sacrificial semiconductor patterns 160SC may include silicon-germanium (SiGe), but the present disclosure is not limited thereto.

Sacrificial pattern capping films 160IP may be disposed between the first source/drain patterns 150 and the sacrificial semiconductor patterns 160SC, and between the second source/drain patterns 250 and the sacrificial semiconductor patterns 160SC. The sacrificial pattern capping films 160IP may also be disposed between the third source/drain patterns 350 and the sacrificial semiconductor patterns 160SC, and between the fourth source/drain patterns 450 and the sacrificial semiconductor patterns 160SC.

The sacrificial pattern capping films 160IP may include a material with an etch selectivity with respect to the first, second, third, and fourth lower patterns BP1, BP2, BP3, and BP4. The sacrificial pattern capping films 160IP may have an etch selectivity with respect to the first source/drain patterns 150, the second source/drain patterns 250, the third source/drain patterns 350, and the fourth source/drain patterns 450. For example, the sacrificial pattern capping films 160IP may include a semiconductor material. Alternatively, the sacrificial pattern capping films 160IP may include an insulating material.

The first and second channel separation structures CCW1 and CCW2 will hereinafter be described, focusing mainly on the first channel separation structure CCW1. That is, the description of the first channel separation structure CCW1 may be directly applicable to the second channel separation structure CCW2.

Referring to FIGS. 1, 4, 5, and 7 through 9, the first channel separation structure CCW1 may include first regions CCW1_R1 and second regions CCW1_R2. The first regions CCW1_R1 of the first channel separation structure CCW may be the regions that contact the first gate structures GS1 and the second gate structures GS2 within the first channel separation structure CCW1. The first regions CCW1_R1 of the first channel separation structure CCW1 may overlap with the first gate structures GS1 and the second gate structures GS2 in the second direction D2. The second regions CCW1_R2 of the first channel separation structure CCW1 may be the regions that contact the first source/drain patterns 150 and the second source/drain patterns 250 within the first channel separation structure CCW1. The second regions CCW1_R2 of the first channel separation structure CCW1 may overlap with the first source/drain patterns 150 and the second source/drain patterns 250 in the second direction D2.

For example, FIG. 8 is a cross-sectional view illustrating the shape of the first regions CCW1_R1 of the first channel separation structure CCW1, and FIG. 9 is a cross-sectional view illustrating the shape of the second regions CCW1_R2 of the first channel separation structure CCW1.

Referring to FIGS. 4 and 8, the width of the first channel separation structure CCW1 in the second direction D2 may continuously increase away from the lower surface 105BS of the field insulating film 105.

Referring to FIGS. 5 and 9, the second regions CCW1_R2 of the first channel separation structure CCW1 may include first portions CCW1_R21 and second portions CCW1_R22, where the width of the first channel separation structure CCW1 increases away from the lower surface 105BS of the field insulating film 105. In both the first portions CCW1_R21 and the second portions CCW1_R22 and the second part CCW1_R22, the width, in the second direction D2, of the first channel separation structure CCW1 may continuously increase away from the lower surface 105BS of the field insulating film 105.

The second portions CCW1_R22 of the second regions CCW1_R2 of the first channel separation structure CCW1 may be disposed on the first portions CCW1_R21 of the second regions CCW1_R2 of the first channel separation structure CCW1. The second portions CCW1_R22 of the second regions CCW1_R2 of the first channel separation structure CCW1 may be directly connected to the first portions CCW1_R21 of the second regions CCW1_R2 of the first channel separation structure CCW1.

There may be steps between the first portions CCW1_R21 and the second portions CCW1_R22 of the second regions CCW1_R2 of the first channel separation structure CCW1. In other words, a width W21 of an uppermost portion of the first channel separation structure CCW1 may be greater in the first portions CCW1_R21 of the second regions CCW1_R2 than in the second portions CCW1_R22 of the second regions CCW1_R2.

The first portions CCW1_R21 of the second regions CCW1_R2 of the first channel separation structure CCW1 may include first width centerlines WCL1, which extend in the third direction D3. The second portions CCW1_R22 of the second regions CCW1_R2 of the first channel separation structure CCW1 may include second width centerlines WCL2, which extend in the third direction D3. The first width centerlines WCL1 may be aligned with the second width centerlines WCL2, respectively, in the third direction D3. In other words, the extensions of the first width centerlines WCL1 may respectively coincide with the second width centerlines WCL2.

For example, the first width centerlines WCL1 may be imaginary lines that bisect the width W21 of corresponding uppermost parts of the first portions CCW1_R21 of the second regions CCW1_R2 of the first channel separation structure CCW1. For example, the second width centerlines WCL2 may be imaginary lines that bisect a width W22 of lowermost parts of the second portions CCW1_R22 of the second regions CCW1_R2 of the first channel separation structure CCW1.

A height H15 from the lower surface 105BS of the field insulating film 105 to the uppermost parts of the first portions CCW1_R21 of the second regions CCW1_R2 of the first channel separation structure CCW1 may be less than a height H16 from the lower surface 105BS of the field insulating film 105 to uppermost parts of the first source/drain patterns 150.

Portions of the first source/drain patterns 150 may overlap with the first portions CCW1_R21 of the second regions CCW1_R2 of the first channel separation structure CCW1 in the third direction D3. Overlapping portions 150_OVR of the first source/drain patterns 150 may overlap with the first portions CCW1_R21 of the second regions CCW1_R2 of the first channel separation structure CCW1 in the third direction D3. The overlapping portions 150_OVR of the first source/drain patterns 150 may be disposed over the first portions CCW1_R21 of the second regions CCW1_R2 of the first channel separation structure CCW1.

Portions of the second source/drain patterns 250 may overlap with the first portions CCW1_R21 of the second regions CCW1_R2 of the first channel separation structure CCW1 in the third direction D3. Portions of the second source/drain patterns 250 may be disposed over the first portions CCW1_R21 of the second regions CCW1_R2 of the first channel separation structure CCW1.

The first portions CCW1_R21 and the second portions CCW1_R22 of the second regions CCW1_R2 of the first channel separation structure CCW1 are illustrated as having no explicit boundaries therebetween, but the present disclosure is not limited thereto. Alternatively, the first portions CCW1_R21 of the second regions CCW1_R2 of the first channel separation structure CCW1 may be explicitly divided from the second portions CCW1_R22 of the second regions CCW1_R2 of the first channel separation structure CCW1 by boundaries.

Referring to FIGS. 4 and 5, the height H15 from the lower surface 105BS of the field insulating film 105 to the uppermost parts of the first portions CCW1_R21 of the second regions CCW1_R2 of the first channel separation structure CCW1 may be less than the height H14 from the lower surface 105BS of the field insulating film 105 to the upper surfaces of the first channel patterns CH1.

In a cross-sectional view such as FIG. 5, the upper surface CCW1_US of the first channel separation structure CCW1 may be on the same plane as the upper surface GCS_US of the gate separation structure GCS.

The upper surface CCW1_US of the first channel separation structure CCW1 may be lower in the first regions CCW1_R1 of the first channel separation structure CCW1 than in the second regions CCW1_R2 of the first channel separation structure CCW1. The height from the lower surface 105BS of the field insulating film 105 to the upper surface CCW1_US of the first channel separation structure CCW1 may be less in the first regions CCW1_R1 than in the second regions CCW1_R2.

For example, FIG. 7 may be a plan view cut at the height level of the second portions CCW1_R22 of the second regions CCW1_R22 of the first channel separation structure CCW1.

Referring to FIG. 7, a width W11, in the second direction D2, of the first channel separation structure CCW1 between the first gate structures GS1 and the second gate structures GS2 may differ from a width W12, in the second direction D2, between the first source/drain patterns 150 and the second source/drain patterns 250. For example, the width W11, in the second direction D2, of the first channel separation structure CCW1 between the first gate structures GS1 and the second gate structures GS2 may be greater than the width W12, in the second direction D2, between the first source/drain patterns 150 and the second source/drain patterns 250.

The first source/drain patterns 150 may overlap with the first channel separation structure CCW1 in the first direction D1 by a first overlap width W13. The second source/drain patterns 250 may overlap with the first channel separation structure CCW1 in the first direction D1 by a second overlap width W14. For example, the first overlap width W13 may be the same as the second overlap width W14.

Source/drain etch stopper films 185 may extend along the outer sidewalls of the first gate spacers 140 and third gate spacers 340, and along the sidewalls of the first source/drain patterns 150, second source/drain patterns 250, third source/drain patterns 350, and fourth source/drain patterns 450. The source/drain etch stopper films 185 may also extend along the upper surface 105US of the field insulating film 105.

Portions of the source/drain etch stopper films 185 may extend along the sidewalls of the first and second channel separation structures CCW1 and CCW2.

Source/drain etch stopper films 185 on the sidewalls of the first and second channel separation structures CCW1 and CCW2 may be portions of the source/drain etch stopper films 185 that remain unremoved after the fabrication of the first source/drain contacts 180, the second source/drain contacts 280, the third source/drain contacts 380, and the fourth source/drain contacts 480.

The source/drain etch stopper films 185 may extend along the upper surfaces of first source/drain patterns 150, second source/drain patterns 250, third source/drain patterns 350, and fourth source/drain patterns 450 that are not connected to the first source/drain contacts 180, the second source/drain contacts 280, the third source/drain contacts 380, and the fourth source/drain contacts 480. For example, the source/drain etch stopper films 185 may extend along the upper surfaces 150US of first lower connection semiconductor patterns, the upper surfaces of second lower connection semiconductor patterns, the upper surfaces 350US of third lower connection semiconductor patterns, and the upper surfaces of fourth lower connection semiconductor patterns. The upper surfaces 150US of the first lower connection semiconductor patterns may be the upper surfaces 150US of the first source/drain patterns 150, and the upper surfaces 350US of the third lower connection semiconductor patterns may be the upper surfaces of the third source/drain patterns 350.

The source/drain etch stopper films 185 may not extend along the sidewalls of the first gate capping patterns 145 and second gate capping patterns 345. Alternatively, the source/drain etch stopper films 185 may extend along the sidewalls of the first gate capping patterns 145 and second gate capping pattern 345.

The source/drain etch stopper films 185 may include at least one of SiN, SiON, SiOCN, SiBN, SiOBN, SiOC, and a combination thereof.

If the source/drain etch stopper films 185 contain the same material as the first channel separation structure CCW1, the boundaries between the source/drain etch stopper films 185 and the first channel separation structure CCW1 may not be distinguishable. Similarly, if the source/drain etch stopper films 185 contain the same material as the second channel separation structure CCW2, the boundaries between the source/drain etch stopper films 185 and the second channel separation structure CCW2 may not be distinguishable. In this case, the source/drain etch stopper films 185 that extend in the third direction D3 over the first source/drain patterns 150, the second source/drain patterns 250, the third source/drain patterns 350, and the fourth source/drain patterns 450 may appear as part of the first channel separation structure CCW1 and/or the second channel separation structure CCW2.

However, the source/drain etch stopper films 185 may not be formed.

The upper interlayer insulating films 190 may be disposed on the first surface 100US of the substrate 100. The upper interlayer insulating films 190 may be disposed on the source/drain etch stopper films 185. The upper interlayer insulating films 190 may be disposed on the first source/drain patterns 150, the second source/drain patterns 250, the third source/drain patterns 350, and the fourth source/drain patterns 450.

The upper interlayer insulating films 190 may include, for example, at least one of silicon oxide, silicon nitride, silicon oxynitride, and a low-k material. The dielectric constant of the low-k material may be less than 3.9, which is the dielectric constant of silicon oxide.

The first source/drain contacts 180 may be disposed on the first source/drain patterns 150. The first source/drain contacts 180 may be disposed on the first upper connection semiconductor patterns 150_2. The first source/drain contacts 180 are not disposed on the first lower connection semiconductor patterns 150_1.

The first source/drain patterns 150 may be disposed between the first source/drain contacts 180 and the sacrificial semiconductor patterns 160SC. For example, the first upper connection semiconductor patterns 150_2 may be disposed between the first source/drain contacts 180 and the sacrificial semiconductor patterns 160SC.

The first source/drain contacts 180 are electrically connected to the first source/drain patterns 150. The first source/drain contacts 180 may be electrically connected to the first upper connection semiconductor patterns 150_2. The first source/drain contacts 180 may not be electrically connected to the first lower connection semiconductor patterns 150_1.

The first source/drain contacts 180 may be disposed between the first channel separation structure CCW1 and the gate separation structure GCS. The first source/drain contacts 180 may be disposed on the upper interlayer insulating films 190. The upper interlayer insulating films 190 are illustrated as not being interposed between the sidewalls of the first source/drain contacts 180 and the first channel separation structure CCW1, but the present disclosure is not limited thereto. Upper surfaces 180US of the first source/drain contacts 180 may be on the same plane as the upper surface CCW1_US of the first channel separation structure CCW1.

The second source/drain contacts 280 may be disposed on the second source/drain patterns 250. The second source/drain contacts 280 are electrically connected to the second source/drain patterns 250. The second source/drain contacts 280 may be disposed on the second upper connection semiconductor patterns to be electrically connected to the second upper connection semiconductor patterns.

The second source/drain contacts 280 may be disposed between the first channel separation structure CCW1 and the gate separation structure GCS. The second source/drain contacts 280 may be disposed on the upper interlayer insulating films 190. The upper interlayer insulating films 190 are illustrated as not being interposed between the sidewalls of the second source/drain contacts 280 and the first channel separation structure CCW1, but the present disclosure is not limited thereto.

The third source/drain contacts 380 may be disposed on the third source/drain patterns 350. The third source/drain contacts 380 may be disposed on third upper connection semiconductor patterns 350_2. The third source/drain contacts 380 are not disposed on the third lower connection semiconductor patterns 350_1. The third source/drain contacts 380 may be electrically connected to the third upper connection semiconductor patterns 350_2. Upper surfaces 380US of the third source/drain contacts 380 may be on the same plane as the upper surface CCW2_US of the second channel separation structure CCW2.

The fourth source/drain contacts 480 may be disposed on the fourth source/drain patterns 450. The fourth source/drain contacts 480 may be disposed on the fourth upper connection semiconductor patterns. The fourth source/drain contacts 480 are not disposed on the fourth lower connection semiconductor patterns. The fourth source/drain contacts 480 may be electrically connected to the fourth upper connection semiconductor patterns within the fourth source/drain patterns 450.

The first source/drain contacts 180, the second source/drain contacts 280, the third source/drain contacts 380, and the fourth source/drain contacts 480 may be full source/drain contacts disposed on the first surface 100US of the substrate 100.

The first contact silicide films 155 may be disposed between the first source/drain contacts 180 and the first source/drain patterns 150. Second contact silicide films 255 may be disposed between the second source/drain contacts 280 and the second source/drain patterns 250. Third contact silicide films 355 may be disposed between the third source/drain contacts 380 and the third source/drain patterns 350. Fourth contact silicide films 455 may be disposed between the fourth source/drain contacts 480 and the fourth source/drain patterns 450.

The first source/drain contacts 180, the second source/drain contacts 280, the third source/drain contacts 380, and the fourth source/drain contacts 480 are illustrated as having a single conductive film structure, but the present disclosure is not limited thereto. Alternatively, the first source/drain contacts 180, the second source/drain contacts 280, the third source/drain contacts 380, and the fourth source/drain contacts 480 may have a multi-conductive film structure including barrier films and plug films. The first source/drain contacts 180, the second source/drain contacts 280, the third source/drain contacts 380, and the fourth source/drain contacts 480 may include at least one of a metal, a conductive metal nitride, a conductive metal carbide, a conductive metal oxide, a conductive metal carbonitride, and a two-dimensional (2D) material. The first contact silicide films 155, the second contact silicide films 255, the third contact silicide films 355, and the fourth contact silicide films 455 may include a metal silicide material.

The 2D material may include a 2D allotrope or a 2D compound. For example, the 2D material may include at least one of graphene, boron nitride (BN), molybdenum sulfide, molybdenum selenide, tungsten sulfide, tungsten selenide, and tantalum sulfide, but the present disclosure is not limited thereto. That is, the 2D material is not particularly limited.

Contact blocking patterns 285 may be disposed on the first source/drain patterns 150, second source/drain patterns 250, third source/drain patterns 350, and fourth source/drain patterns 450 that are not connected to the first source/drain contacts 180, the second source/drain contacts 280, the third source/drain contacts 380, and the fourth source/drain contacts 480. The contact blocking patterns 285 may be disposed on the first lower connection semiconductor patterns 350_1 and the third lower connection semiconductor patterns 350_1. The contact blocking patterns 285 may be disposed on the second lower connection semiconductor patterns and the fourth lower connection semiconductor patterns.

The contact blocking patterns 285 may be disposed on the upper interlayer insulating films 190. Each of the contact blocking patterns 285 may include opposing upper and lower surfaces 285US and 285BS in the third direction D3. The lower surfaces 285BS of the contact blocking patterns 285 may face the first source/drain patterns 150, the second source/drain patterns 250, the third source/drain patterns 350, and the fourth source/drain patterns 450.

For example, the upper surfaces 285US of the contact blocking patterns 285 may be on the same plane as the upper surfaces 145US of the first gate capping patterns 145 and the upper surfaces 345US of the second gate capping patterns 345. In a cross-sectional view such as FIG. 5, the upper surfaces 285US of the contact blocking patterns 285 may be on the same plane as the upper surface CCW1_US of the first channel separation structure CCW1 and the upper surface CCW2_US of the second channel separation structure CCW2.

The contact blocking patterns 285 may not contact the first source/drain patterns 150, the second source/drain patterns 250, the third source/drain patterns 350, and the fourth source/drain patterns 450. For example, the contact blocking patterns 285 may not contact portions of the source/drain etch stopper films 185 that extend along the upper surfaces 150US of the first source/drain patterns 150. That is, the contact blocking patterns 285 may not contact portions of the source/drain etch stopper films 185 that extend along the upper surfaces of the first lower connection semiconductor patterns 150_1.

A depth d11 from the upper surface CCW1_US of the first channel separation structure CCW1 to the uppermost portions of the first source/drain patterns 150 may be greater than a depth d12 from the upper surface CCW1_US of the first channel separation structure CCW1 to the lower surfaces 285BS of the contact blocking patterns 285.

Alternatively, the contact blocking patterns 285 may contact the portions of the source/drain etch stopper films 185 that extend along the upper surfaces 150US of the first source/drain patterns 150. The contact blocking patterns 285 may not penetrate the source/drain etch stopper films 185.

The contact blocking patterns 285 may contain or be formed of an insulating material. The contact blocking patterns 285 may include a material with etch selectivity with respect to the upper interlayer insulating films 190. For example, the contact blocking patterns 285 may include at least one of SiN, SiON, SiOCN, SiBN, SIOBN, SiOC, and a combination thereof.

The first backside wiring lines 290 and the second backside wiring lines 295 may be disposed within the substrate 100. The first backside wiring lines 290 and the second backside wiring lines 295 may be disposed on the lower surfaces BP1_BS, BP2_BS, BP3_BS, and BP4_BS of the first, second, third, and fourth lower patterns BP1, BP2, BP3, and BP4. The first backside wiring lines 290 and the second backside wiring lines 295 are illustrated as extending in the first direction D1, but the present disclosure is not limited thereto.

For example, the first backside wiring lines 290 and the second backside wiring lines 295 may include line portions and via portions. The via portions of the first backside wiring line 290 may protrude in the third direction D3 from the line portions of the first backside wiring line 290. The via portions of the second backside wiring line 295 may protrude in the third direction D3 from the line portions of the second backside wiring line 295. The first backside wiring lines 290 and the second backside wiring lines 295 may not include via portions.

The first backside source/drain contacts 175 may be disposed within the first lower pattern BP1. The first backside source/drain contacts 175 may be disposed between the first source/drain patterns 150 and the first backside wiring lines 290.

The first backside source/drain contacts 175 may be connected to the first source/drain patterns 150. The first backside source/drain contacts 175 may electrically connect the first source/drain patterns 150 and the first backside wiring lines 290. For example, the first backside source/drain contacts 175 may electrically connect the first lower connection semiconductor patterns 150_1 and the first backside wiring lines 290. The first backside wiring lines 290 may not be electrically connected to the first source/drain contacts 180. The first backside source/drain contacts 175 does not connect to the first upper connection semiconductor patterns 150_2.

The third backside source/drain contacts 375 may be disposed within the third lower pattern BP3. The third backside source/drain contacts 375 may be disposed between the third source/drain patterns 350 and the second backside wiring lines 295.

The third backside source/drain contacts 375 may be connected to the third source/drain patterns 350. The third backside source/drain contacts 375 may electrically connect the third source/drain patterns 350 and the second backside wiring lines 295. For example, the third backside source/drain contacts 375 may electrically connect the third lower connection semiconductor patterns 350_1 and the second backside wiring lines 295. The second backside wiring lines 295 may not be electrically connected to the third source/drain contacts 380. The third backside source/drain contacts 375 are not connected to the third upper connection semiconductor patterns 350_2.

Alternatively, the second backside source/drain contacts 275 may connect the first backside wiring lines 290 and the second source/drain patterns 250, and the fourth backside source/drain contacts may connect the second backside wiring lines 295 and the fourth source/drain patterns 450.

First backside contact silicide films 156 may be disposed between the first backside source/drain contacts 175 and the first source/drain patterns 150. Third backside contact silicide films 356 may be disposed between the third backside source/drain contacts 375 and the third source/drain patterns 350. Alternatively, second backside contact silicide films may be disposed between the second backside source/drain contacts and the second source/drain patterns 250. Fourth backside contact silicide films may be disposed between the fourth backside source/drain contacts and the fourth source/drain patterns 450.

The first backside source/drain contacts 175 and the third backside source/drain contacts 375 are illustrated as being single conductive films, but the present disclosure is not limited thereto. Alternatively, the first backside source/drain contacts 175 and the third backside source/drain contacts 375 may have a multi-conductive film structure including barrier films and filling films. The first backside wiring lines 290 and the second backside wiring lines 295 are illustrated as being single conductive films, but the present disclosure is not limited thereto. Alternatively, the first backside wiring lines 290 and the second backside wiring lines 295 may have a multi-conductive film structure including barrier films and filling films.

The first backside source/drain contacts 175 and the third backside source/drain contacts 375 may include, for example, at least one of a metal, a conductive metal nitride, a conductive metal carbide, a conductive metal oxide, a conductive metal carbonitride, and a 2D material. The first backside wiring lines 290 and the second backside wiring lines 295 may include, for example, at least one of a metal, a conductive metal nitride, a conductive metal carbide, a conductive metal oxide, a conductive metal carbonitride, and a 2D material. The first backside contact silicide films 156 and the third backside contact silicide films 356 may include a metal silicide material.

The first source/drain patterns 150 and the third source/drain patterns 350 are illustrated as being connected to different backside wiring lines from one another, but the present disclosure is not limited thereto. The first source/drain patterns 150 and the third source/drain patterns 350 may be connected to either the first backside wiring lines 290 or the second backside wiring lines 295. In this case, the width of backside wirings connected to the first source/drain patterns 150 and the third source/drain patterns 350 may be larger than the width of the first backside wiring lines 290 and the second backside wiring lines 295.

Front-side source/drain contacts may not be formed on source/drain patterns connected to backside source/drain contacts. If front-side source/drain contacts are formed on source/drain patterns connected to backside source/drain contacts, unnecessary capacitance may be generated between the front-side source/drain contacts and gate electrodes.

However, since front-side source/drain contacts are not formed on source/drain patterns connected to backside source/drain contacts, capacitance may not be generated between the front-side source/drain contacts and gate electrodes. As a result, the performance and reliability of a semiconductor device can be improved.

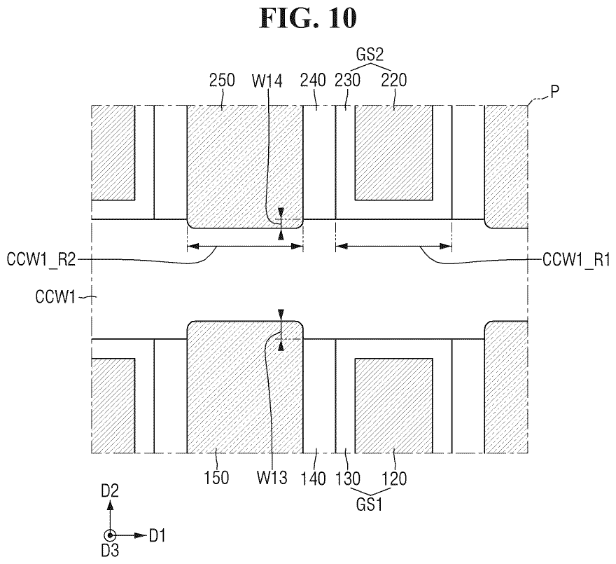

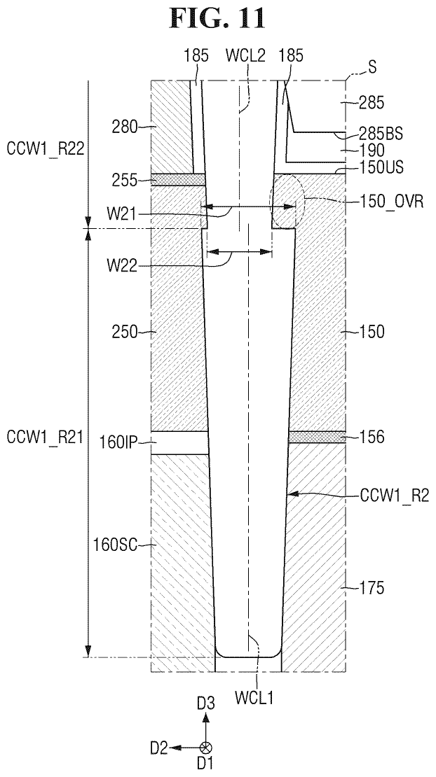

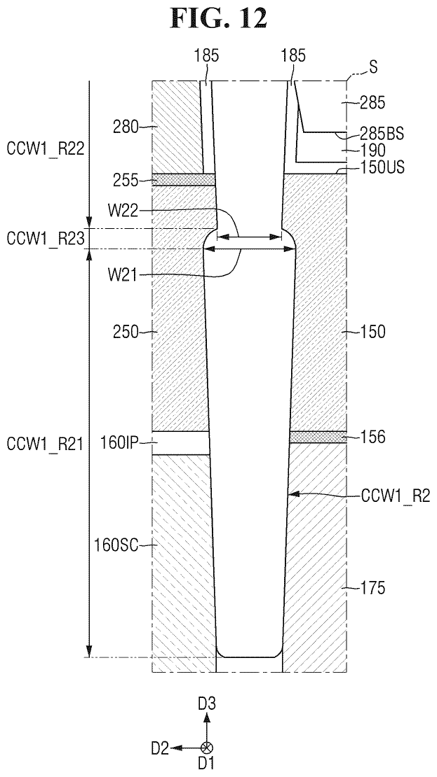

FIGS. 10 and 11 are drawings illustrating a semiconductor device according to one or more embodiments of the present disclosure. FIG. 12 is a drawing illustrating a semiconductor device according to one or more embodiments of the present disclosure. For convenience, the embodiments of FIGS. 10 through 12 will hereinafter be described, focusing mainly on differences from what has been described with reference to FIGS. 1 through 9.

FIG. 10 is a plan view illustrating another example of part P of FIG. 1. FIGS. 11 and 12 are enlarged cross-sectional views illustrating examples of part S of FIG. 5.

Referring to FIGS. 10 and 11, a first overlap width W13 may differ from a second overlap width W14.

For example, a width W13 by first source/drain patterns 150 overlaps with a first channel separation structure CCW1 in a first direction D1 may be greater than a width W14 by which second source/drain patterns 250 overlap with the first channel separation structure CCW1 in the first direction D1.

A first width centerline WCL1 may be spaced apart from a second width centerline WCL2 in a second direction D2. The first width centerline WCL1 may be misaligned with the second width centerline WCL2 in a third direction D3. The extension of the first width centerline WCL1 may not meet the second width centerline WCL2.

Portions of the second source/drain patterns 250 are illustrated as overlapping with first portions CCW1_R21 of second regions CCW1_R2 of the first channel separation structure CCW1 in the third direction D3, but the present disclosure is not limited thereto. That is, the second source/drain patterns 250 may not include overlapping portions with the first portions CCW1_R21 of the second regions CCW1_R2 of the first channel separation structure CCW1.

Referring to FIG. 12, a second region CCW1_R2 of a first channel separation structure CCW1 may further include a third portion CCW1_R23, which is disposed between a first portion CCW1_R21 and a second portion CCW1_R22 of the second region CCW1_R2 of the first channel separation structure CCW1.

In the third portion CCW1_R23 of the second region CCW1_R2 of the first channel separation structure CCW1, the width, in a second direction D2, of the first channel separation structure CCW1 may decrease away from a lower surface 105BS of a field insulating film.

The first and third portions CCW1_R21 and CCW1_R23 of the second region CCW1_R2 of the first channel separation structure CCW1 are illustrated as having no distinct boundary therebetween, but the present disclosure is not limited thereto. Alternatively, the first portion CCW1_R21 of the second region CCW1_R2 of the first channel separation structure CCW1 may be explicitly divided from the third portion CCW1_R23 of the second region CCW1_R2 of the first channel separation structure CCW1 by a boundary.

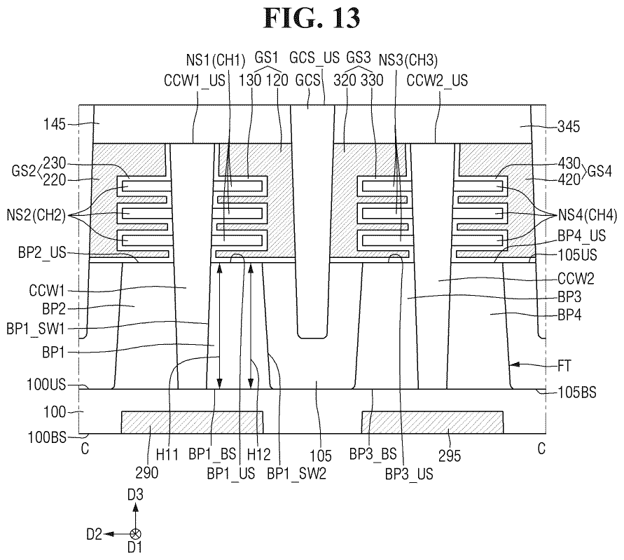

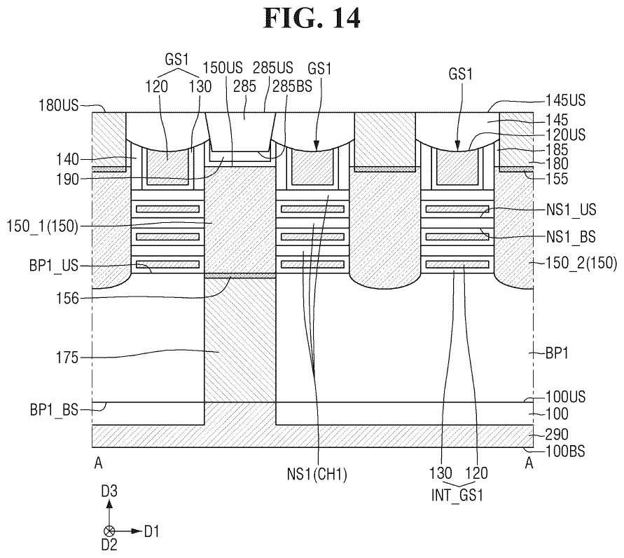

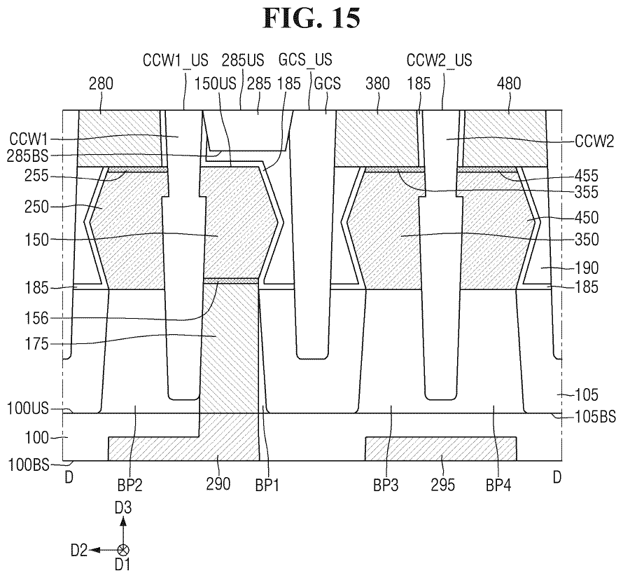

FIG. 13 is a drawing illustrating a semiconductor device according to one or more embodiments of the present disclosure. FIGS. 14 and 15 are drawings illustrating a semiconductor device according to one or more embodiments of the present disclosure. For convenience, the embodiments of FIGS. 13 through 15 will hereinafter be described, focusing mainly on differences from what has been described with reference to FIGS. 1 through 9.

Referring to FIG. 13, a depth H11 from an upper surface BP1_US of a first lower pattern BP1 to a lowermost portion of the first channel separation structure CCW1 may be the same as a depth H12 from the upper surface BP1_US of the first lower pattern BP1 to a lower surface 105BS of a field insulating film 105.

The first and second channel separation structures CCW1 and CCW2 may extend to the first surface 100US of the substrate 100.

Referring to FIGS. 14 and 15, sacrificial semiconductor patterns (“160SC” of FIGS. 2, 3, and 5) may not be disposed within first, second, third, and fourth lower patterns BP1, BP2, BP3, and BP4.

No sacrificial semiconductor patterns may be disposed between a substrate 100 and first source/drain patterns 150, second source/drain patterns 250, third source/drain patterns 350, and fourth source/drain patterns 450. No sacrificial semiconductor patterns may be disposed below first source/drain patterns 150, second source/drain patterns 250, third source/drain patterns 350, and fourth source/drain patterns 450 that are connected to first source/drain contacts 180, second source/drain contacts 280, third source/drain contacts 380, and fourth source/drain contacts 480.

For example, no sacrificial semiconductor patterns may be disposed between the substrate 100 and first upper connection semiconductor patterns 150_2 of the first source/drain patterns 150.

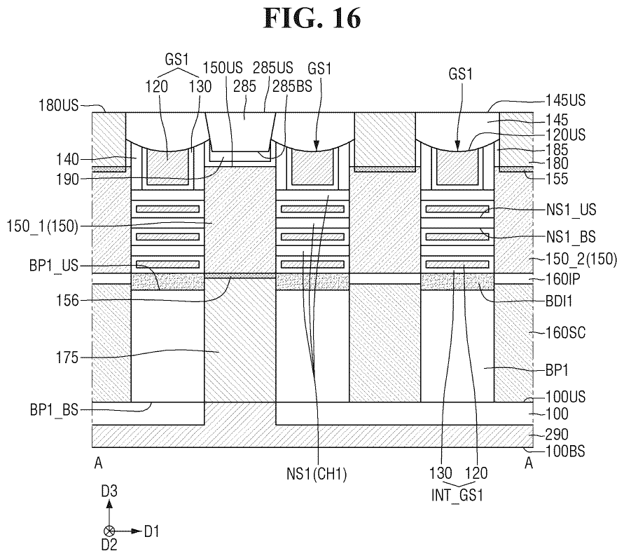

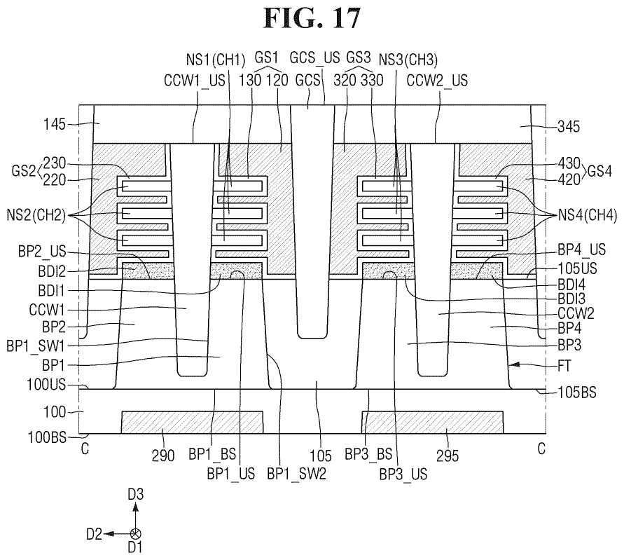

FIGS. 16 and 17 are drawings illustrating a semiconductor device according to one or more embodiments. For convenience, the embodiments of FIGS. 13 through 15 will hereinafter be described, focusing mainly on differences from what has been described with reference to FIGS. 1 through 9.

Referring to FIGS. 16 and 17, the semiconductor device according to one or more embodiments of the present disclosure may further include first lower insulating patterns BDI1, second lower insulating patterns BDI2, third lower insulating patterns BDI3, and fourth lower insulating patterns BDI4.

The first lower insulating patterns BDI1 may be disposed between a first lower pattern BP1 and first channel patterns CH1. The first lower insulating patterns BDI1 may contact an upper surface BP1_US of the first lower pattern BP1. The first lower insulating patterns BDI1 may be disposed between the first lower pattern BP1 and first gate structures GS1.

The second lower insulating patterns BDI2 may be disposed between a second lower pattern BP2 and second channel patterns CH2. The second lower insulating pattern BDI2 may contact an upper surface BP2_US of the second lower pattern BP2. The second lower insulating patterns BDI2 may be disposed between the second lower pattern BP2 and second gate structures GS2.

The third lower insulating patterns BDI3 may be disposed between a third lower pattern BP3 and third channel patterns CH3. The third lower insulating patterns BDI3 may contact an upper surface BP3_US of the third lower pattern BP3. The third lower insulating patterns BDI3 may be disposed between the third lower pattern BP3 and third gate structures GS3.

The fourth lower insulating patterns BDI4 may be disposed between a fourth lower pattern BP4 and fourth channel patterns CH4. The fourth lower insulating patterns BDI4 may contact an upper surface BP4_US of the fourth lower pattern BP4. The fourth lower insulating patterns BDI4 may be disposed between the fourth lower pattern BP4 and fourth gate structures GS4.

The first lower insulating patterns BDI1 may be spaced apart from the second lower insulating patterns BDI2 in a second direction D2. A first channel separation structure CCW1 may separate the first lower insulating patterns BDI1 and the second lower insulating patterns BDI2.

The third lower insulating patterns BDI3 may be spaced apart from the fourth lower insulating patterns BDI4 in the second direction D2. A second channel separation structure CCW2 may separate the third lower insulating patterns BDI3 and the fourth lower insulating patterns BDI4.

The first lower insulating patterns BDI1, the second lower insulating patterns BDI2, the third lower insulating patterns BDI3, and the fourth lower insulating patterns BDI4 may not extend along an upper surface 105US of a field insulating film 105. The first lower insulating patterns BDI1, the second lower insulating patterns BDI2, the third lower insulating patterns BDI3, and the fourth lower insulating patterns BDI4 may not cover the upper surface 105US of the field insulating film 105.

For example, each of the first lower insulating patterns BDI1 may include opposing upper and lower surfaces in a third direction D3. The lower surfaces of the first lower insulating patterns BDI1 may contact the upper surface BP1_US of the first lower pattern BP1. The upper surfaces of the first lower insulating patterns BDI1 may be higher than the upper surface 105US of the field insulating film 105 based on a lower surface 105BS of the field insulating film 105. The upper surfaces of the first lower insulating patterns BDI1 may protrude beyond the upper surface 105US of the field insulating film 105.

The first gate structures GS1 will hereinafter be described as an example. First gate insulating films 130 may contact the upper surfaces of the first lower insulating patterns BDI1.

The first lower insulating patterns BDI1, the second lower insulating patterns BDI2, the third lower insulating patterns BDI3, and the fourth lower insulating patterns BDI4 may include at least one of SiN, SiON, SiCN, and SiOCN. Alternatively, the first lower insulating patterns BDI1, the second lower insulating patterns BDI2, the third lower insulating patterns BDI3, and the fourth lower insulating patterns BDI4 may include silicon oxide.

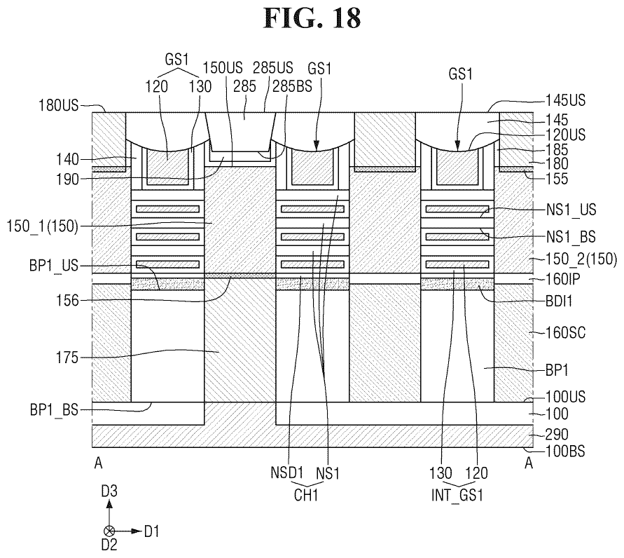

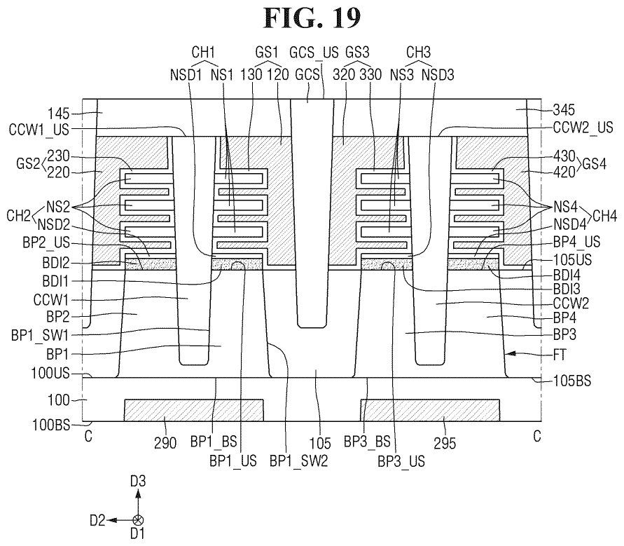

FIGS. 18 and 19 are drawings illustrating a semiconductor device according to one or more embodiments of the present disclosure. For convenience, the embodiments will hereinafter be described, focusing mainly on differences from what has been described with reference to FIGS. 16 and 17.

Referring to FIGS. 18 and 19, each of first channel patterns CH1 may further include a first dummy sheet pattern NSD1, which is disposed between a first lower insulating pattern BDI1 and first sheet patterns NS1. The first dummy sheet pattern NSD1 may contact the first lower insulating pattern BDI1.

Each of second channel patterns CH2 may further include a second dummy sheet pattern NSD2, which is disposed between a second lower insulating pattern BDI2 and second sheet patterns NS2. The second dummy sheet pattern NSD2 may contact the second lower insulating pattern BDI2.

Each of third channel patterns CH3 may further include a third dummy sheet pattern NSD3, which is disposed between a third lower insulating pattern BDI3 and third sheet patterns NS3. The third dummy sheet pattern NSD3 may contact the third lower insulating pattern BDI3.

Each of fourth channel patterns CH4 may further include a fourth dummy sheet pattern NSD4, which is disposed between a fourth lower insulating pattern BDI4 and fourth sheet patterns NS4. The fourth dummy sheet pattern NSD4 may contact the fourth lower insulating pattern BDI4.

The thickness, in a third direction D3, of dummy sheet patterns (NSD1, NSD2, NSD3, and NSD4) is less than the thickness, in the third direction D3, of sheet patterns (NS1, NS2, NS3, and NS4). The dummy sheet patterns (NSD1, NSD2, NSD3, and NSD4) may include the same material as the sheet patterns (NS1, NS2, NS3, and NS4).

The first dummy sheet pattern NSD1 will hereinafter be described as an example. Since the first dummy sheet pattern NSD1 contacts the upper surface of the first lower insulating pattern BDI1, first gate insulating films 130 may not contact the upper surface of the first lower insulating pattern BDI1.

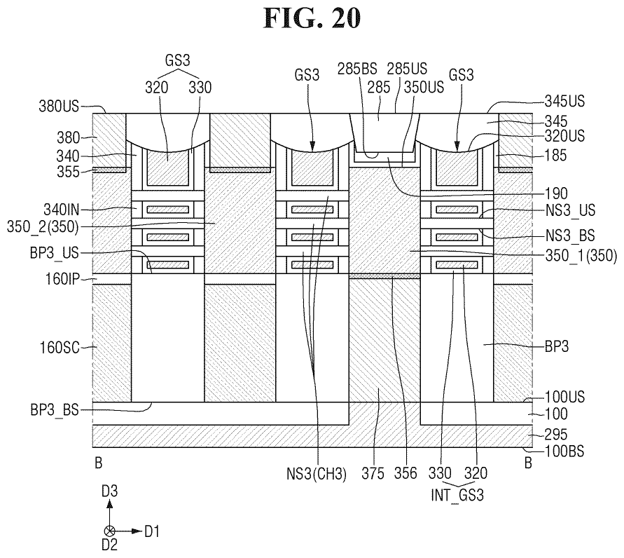

FIG. 20 is a drawing illustrating a semiconductor device according to one or more embodiments of the present disclosure. For convenience, the embodiment of FIG. 20 will hereinafter be described, focusing mainly on differences from what has been described with reference to FIGS. 1 through 9.

Referring to FIG. 20, the semiconductor device according to one or more embodiments of the present disclosure may further include inner spacers 340 IN, which may be disposed between third source/drain patterns 350 and third inner gate structures INT_GS3.

The inner spacers 340 IN may be disposed between a third lower pattern BP3 and third sheet patterns NS3, and between the third sheet patterns NS3 that are adjacent to one another in a third direction D3. The third inner gate structures INT_GS3 may not contact the third source/drain patterns 350.

The inner spacers 340 IN may include, for example, at least one of SiN, SiON, SiO2, SiOCN, SiBN, SiOBN, SiOC, and a combination thereof.

The inner spacers 340 IN may also be disposed between a first lower pattern (“BP1” of FIG. 2) and first sheet patterns NS1, and between the first sheet patterns NS1 that are adjacent to one another in the third direction D3.

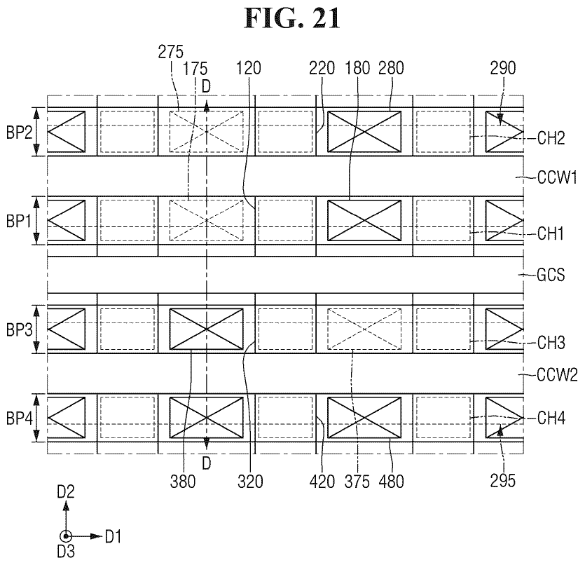

FIGS. 21 and 22 are drawings illustrating a semiconductor device according to one or more embodiments of the present disclosure. For convenience, the description will focus mainly on aspects differing from those described with reference to FIGS. 1 through 9.

Specifically, FIG. 21 is a layout view illustrating a semiconductor device according to one or more embodiments of the present disclosure, and FIG. 22 is a cross-sectional view taken along line D-D of FIG. 21.

Referring to FIGS. 21 and 22, first and second backside source/drain contacts 175 and 275 may be adjacent to each other in a second direction D2.

The second backside source/drain contact 275 may be disposed within a second lower pattern BP2. Second contact silicide films 256 may be disposed between the second backside source/drain contact 275 and second source/drain patterns 250.

The first channel separation structure CCW1 may be disposed between the first backside source/drain contact 175 and the second backside source/drain contact 275. The first source/drain patterns 150 connected to the first backside source/drain contact 175 and the second source/drain patterns 250 connected to the second backside source/drain contact 275 may both contact a single first channel separation structure CCW1. The first source/drain patterns 150 connected to the first backside source/drain contact 175 and the second source/drain patterns 250 connected to the second backside source/drain contact 275 may be aligned in the second direction D2.

The first backside source/drain contact 175 and the second backside source/drain contact 275, adjacent in the second direction D2, may be connected to the first backside wiring lines 290.

Contact blocking patterns 285 may be disposed on the first source/drain patterns 150 and the second source/drain patterns 250. The contact blocking patterns 285 may extend in the second direction D2. A single contact blocking pattern 285 may be disposed over multiple first or second source/drain patterns 150 or 250.

For example, the contact blocking patterns 285 may be disposed on the first channel separation structure CCW1. The contact blocking patterns 285 may intersect the first channel separation structure CCW1.

From a cross-sectional perspective, when a single contact blocking pattern 285 is disposed over the first or second source/drain patterns 150 or 250, the contact blocking pattern may cover the upper surface of the first channel separation structure CCW1. From a cross-sectional view, the upper surface GCS_US of the gate separation structure may be higher than the upper surface of the first channel separation structure CCW1 based on a first surface 100US of a substrate 100.

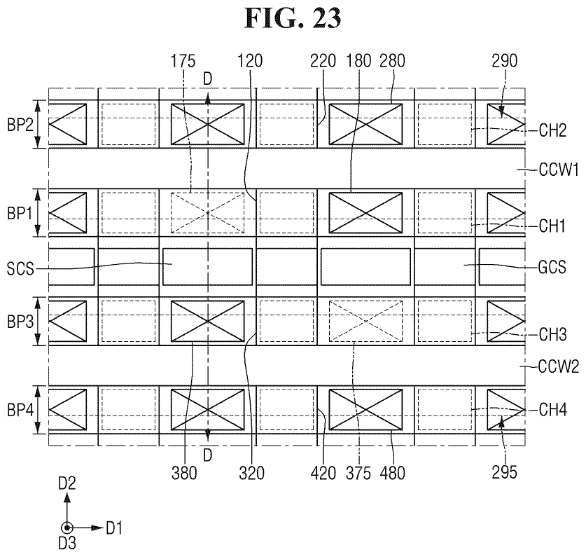

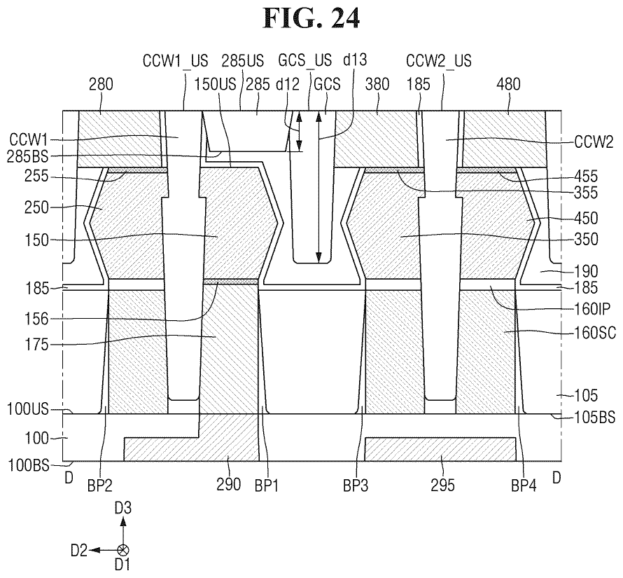

FIGS. 23 and 24 are drawings illustrating a semiconductor device according to one or more embodiments of the present disclosure. For convenience, the embodiments of FIGS. 23 and 24 will hereinafter be described, focusing mainly on differences from what has been described with reference to FIGS. 1 through 9.

Specifically, FIG. 23 is a layout view illustrating a semiconductor device according to one or more embodiments of the present disclosure, and FIG. 24 is a cross-sectional view taken along line D-D of FIG. 23.

Referring to FIGS. 23 and 24, the semiconductor device according to one or more embodiments of the present disclosure may further include source/drain separation structures SCS, which may be disposed on a field insulating film 105.

The source/drain separation structures SCS may be disposed on an upper surface 105US of the field insulating film 105. The source/drain separation structures SCS may not contact the field insulating film 105.

The source/drain separation structures SCS may be disposed between gate separation structures GCS, which are adjacent to one another in a first direction D1.

Alternatively, the gate separation structures GCS may be disposed between the source/drain separation structures SCS, which are adjacent to one another in the first direction D1. The source/drain separation structures SCS and the gate separation structures GCS may be alternately arranged along the first direction D1.

First source/drain patterns 150 may be disposed between the source/drain separation structures SCS and a first channel separation structure CCW1. Second source/drain patterns 250 may be disposed between the source/drain separation structures SCS and the first channel separation structure CCW1. Third source/drain patterns 350 may be disposed between the source/drain separation structures SCS and a second channel separation structure CCW2. Fourth source/drain patterns 450 may be disposed between the source/drain separation structures SCS and the second channel separation structure CCW2.

Upper surfaces SCS_US of the source/drain separation structures SCS may be on the same plane as upper surfaces GCS_US of the gate separation structures GCS. The upper surfaces SCS_US of the source/drain separation structures SCS may be on the same plane as an upper surface CCW1_US of the first channel separation structure CCW1. The upper surfaces SCS_US of the source/drain separation structures SCS may be on the same plane as an upper surface CCW2_US of the second channel separation structure CCW2. The upper surfaces SCS_US of the source/drain separation structures SCS may be on the same plane as upper surfaces 285US of the contact blocking patterns 285.

For example, the height of the source/drain separation structures SCS in a third direction D3 may be less than the height of the gate separation structures GCS in the third direction D3.

For example, a depth d13 from the upper surface CCW1_US of the first channel separation structure CCW1 to the lower surfaces of the source/drain separation structures SCS may be greater than a depth d12 from the upper surface CCW1_US of the first channel separation structure CCW1 to lower surfaces 285BS of the contact blocking patterns 285. Alternatively, in another example, the depth d13 from the upper surface CCW1_US of the first channel separation structure CCW1 to the lower surfaces of the source/drain separation structures SCS may be the same as the depth d12 from the upper surface CCW1_US of the first channel separation structure CCW1 to lower surfaces 285BS of the contact blocking patterns 285.

The source/drain separation structure SCS may include, for example, at least one of SiN, SiON, SiOCN, SiBN, SiOBN, SiOC, and a combination thereof.

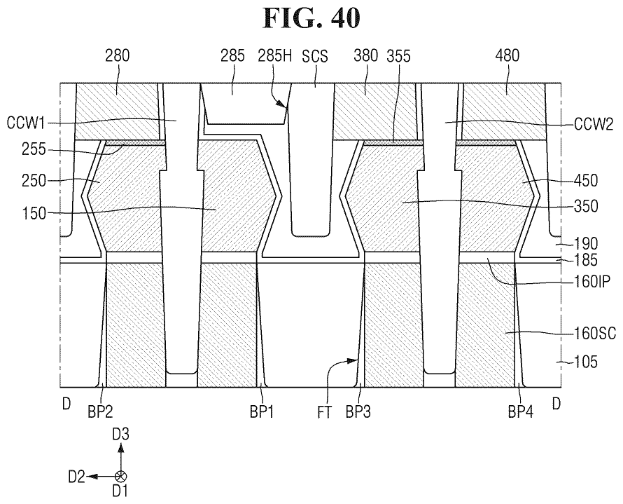

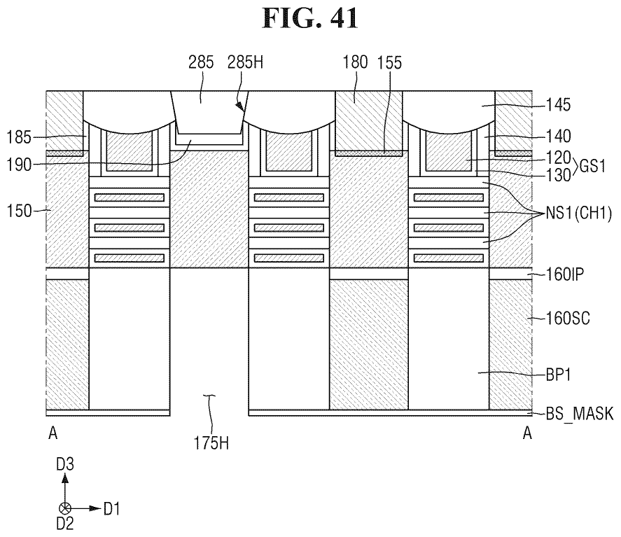

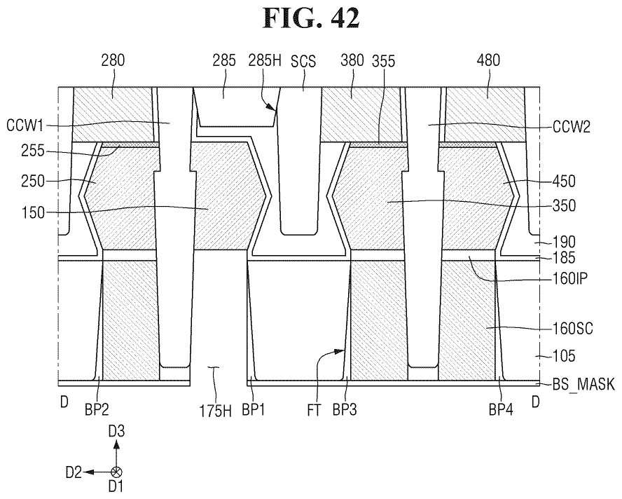

FIGS. 25 through 42 are diagrams illustrating intermediate steps of a method of fabricating a semiconductor device according to one or more embodiments of the present disclosure.

Referring to FIGS. 25 through 27, first, second, third, and fourth lower patterns BP1, BP2, BP3, and BP4 may be formed on a support substrate 200.

The support substrate 200 may be formed of or include a semiconductor material. The support substrate 200 may be a Si substrate or a silicon-on-insulator (SOI) substrate. Alternatively, the support substrate 200 may include, for example, SiGe, SiGe-on-insulator (SGOI), indium antimonide, a lead telluride compound, indium arsenide, indium phosphide, gallium arsenide, or gallium antimonide, but the present disclosure is not limited thereto.

First and second pre-lower patterns may be formed on the support substrate 200. A fin trench FT may separate the first and second pre-lower patterns.

First and second channel separation structures CCW1 and CCW2 may be formed on the support substrate 200. The first channel separation structure CCW1 may divide the first pre-lower pattern, thereby forming first and second lower patterns BP1 and BP2. The second channel separation structure CCW2 may divide the second pre-lower pattern, thereby forming third and fourth lower patterns BP3 and BP4.

During the formation of the first, second, third, and fourth lower patterns BP1, BP2, BP3, and BP4, pre-channel patterns may be formed on the first, second, third, and fourth lower patterns BP1, BP2, BP3, and BP4. Each of the pre-channel patterns may include sacrificial patterns and active patterns, which are alternately stacked. The active patterns may become sheet patterns later by a subsequent process.

Dummy gate electrodes may be formed on the first, second, third, and fourth lower patterns BP1, BP2, BP3, and BP4. The dummy gate electrodes may intersect the pre-channel patterns.

After the formation of the dummy gate electrodes, sacrificial semiconductor patterns 160SC may be formed within the first, second, third, and fourth lower patterns BP1, BP2, BP3, and BP4. Alternatively, the sacrificial semiconductor patterns 160SC may be formed only in regions connected to backside source/drain contacts. Thereafter, sacrificial pattern capping films 160IP may be formed on the sacrificial semiconductor patterns 160SC.

Contrary to what has been described, the sacrificial semiconductor patterns 160SC may also be formed before the formation of the first, second, third, and fourth lower patterns BP1, BP2, BP3, and BP4. In this case, the sacrificial semiconductor patterns 160SC may be formed within the first and second pre-lower patterns.

First source/drain patterns 150, second source/drain patterns 250, third source/drain patterns 350, and fourth source/drain patterns 450 may be formed on the first, second, third, and fourth lower patterns BP1, BP2, BP3, and BP4. For example, the first source/drain patterns 150, the second source/drain patterns 250, the third source/drain patterns 350, and the fourth source/drain patterns 450 may be formed on the sacrificial pattern capping films 160IP. The first source/drain patterns 150, the second source/drain patterns 250, the third source/drain patterns 350, and the fourth source/drain patterns 450 may be formed within the pre-channel patterns.

Source/drain etch stopper films 185 and upper interlayer insulating films 190 may be formed on the first source/drain patterns 150, the second source/drain patterns 250, the third source/drain patterns 350, and the fourth source/drain patterns 450.

After the formation of the upper interlayer insulating films 190, the dummy gate electrodes may be removed. As a result, the pre-channel patterns may be exposed. The sacrificial patterns may be removed from within the exposed pre-channel patterns, thereby forming first channel patterns CH1, second channel patterns CH2, third channel patterns CH3, and fourth channel patterns CH4.

After the formation of the first channel patterns CH1, the second channel patterns CH2, the third channel patterns CH3, and the fourth channel patterns CH4, pre-gate electrodes 120PR and pre-gate insulating films 130PR may be formed. Pre-gate capping patterns 145PR may be formed on the pre-gate electrodes 120PR and the pre-gate insulating films 130PR.

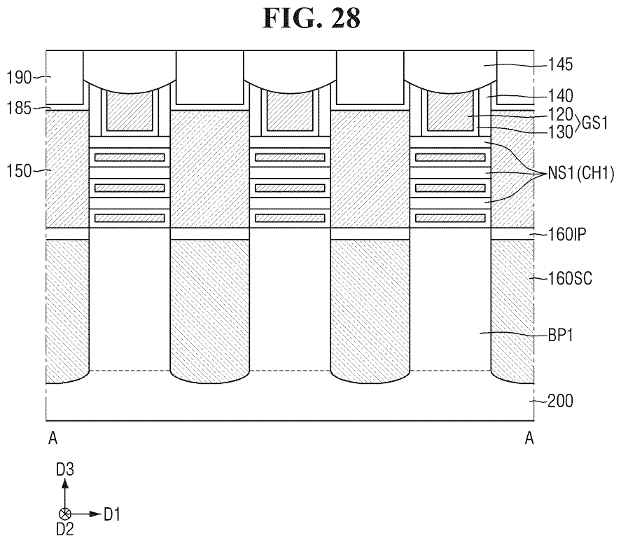

Referring to FIGS. 28 through 30, a gate separation structure GCS may be formed on a field insulating film 105.

The gate separation structure GCS may be formed between the first and second channel separation structures CCW1 and CCW2. The pre-gate electrodes 120PR and the pre-gate insulating films 130PR may be patterned by the gate separation structure GCS. As a result, first gate electrodes 120, second gate electrodes 220, third gate electrodes 320, fourth gate electrodes 420, first gate insulating films 130, second gate insulating films 230, third gate insulating films 330, and fourth gate insulating films 430 may be formed. The gate separation structure GCS may cut the pre-gate capping patterns 145PR. As a result, first gate capping patterns 145 and second gate capping patterns 345 may be formed.

A source/drain separation structure SCS may be formed within upper interlayer insulating films 190. The source/drain separation structure SCS may be formed between the first and second channel separation structures CCW1 and CCW2. The source/drain separation structure SCS may be formed between source/drain patterns that are adjacent to each other in a second direction D2. For example, the source/drain separation structure SCS may be formed between the first source/drain patterns 150 and the third source/drain patterns 350.

Alternatively, the gate separation structure GCS may be formed between source/drain patterns that are adjacent to each other in the second direction D2. In this case, the source/drain separation structure SCS may not be formed.

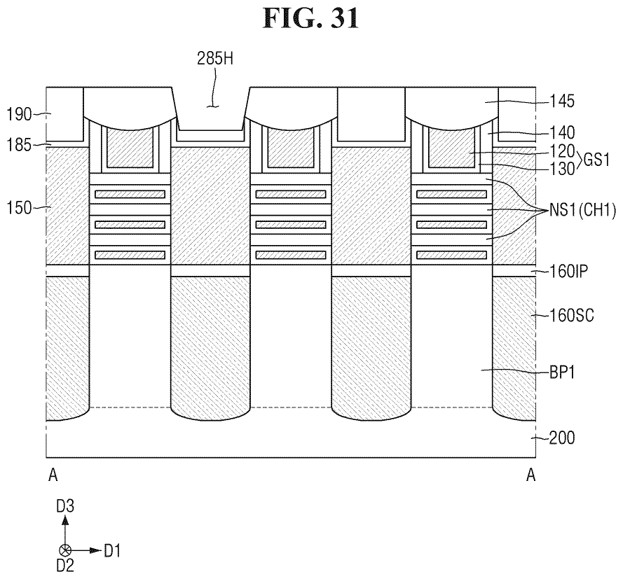

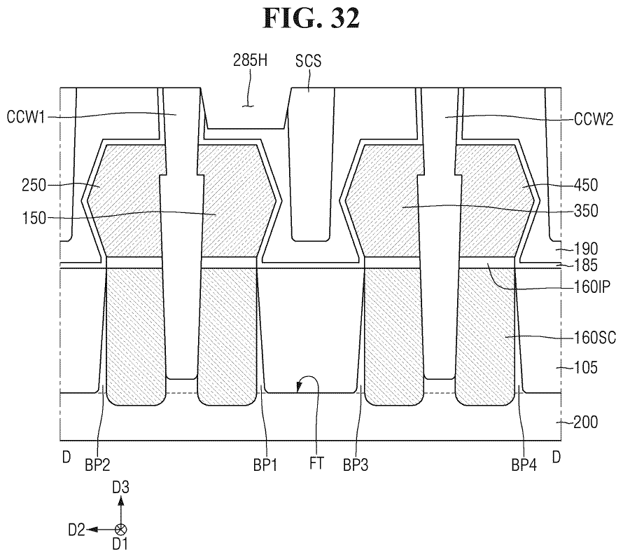

Referring to FIGS. 31 and 32, contact blocking pattern holes 285H may be formed within the upper interlayer insulating films 190.

During the formation of the contact blocking pattern holes 285H, parts of the source/drain etch stopper films 185 and first gate capping patterns 145 may be etched. During the formation of the contact blocking pattern holes 285H, part of the source/drain separation structure SCS may be etched. The contact blocking pattern holes 285H do not expose the first source/drain patterns 150.

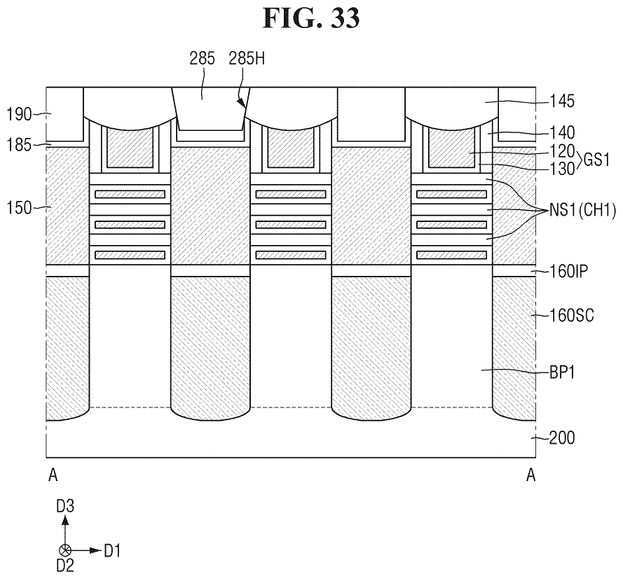

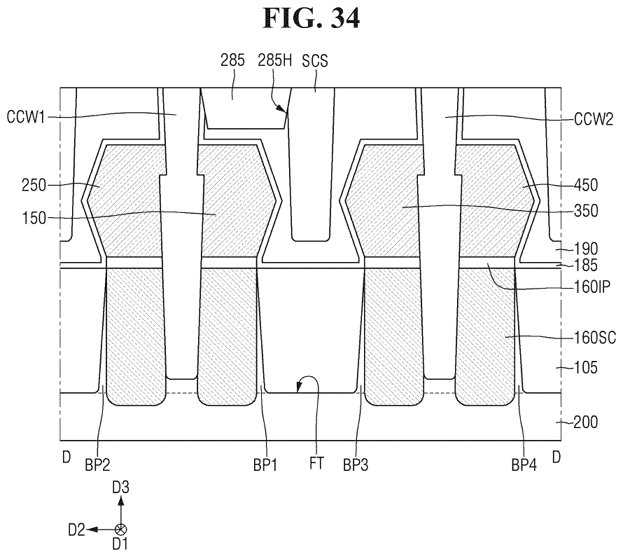

Referring to FIGS. 33 and 34, contact blocking patterns 285 may be formed within upper interlayer insulating films 190.

The contact blocking patterns 285 fill the contact blocking pattern holes 285H. The contact blocking patterns 285 may be formed of an insulating material with etch selectivity with respect to the upper interlayer insulating films 190.

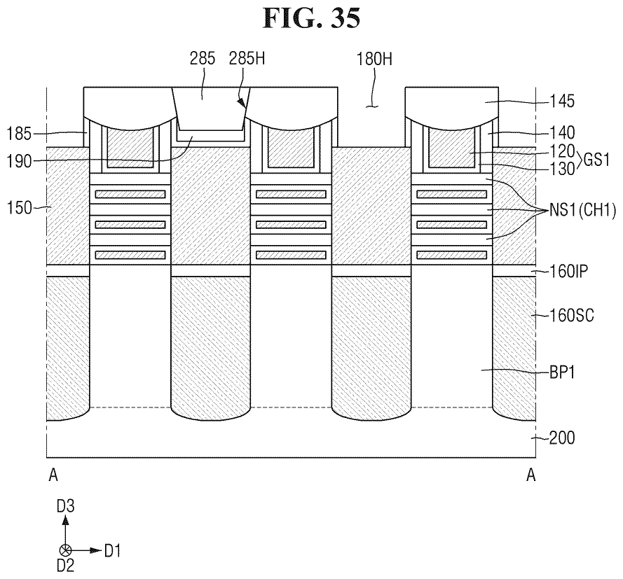

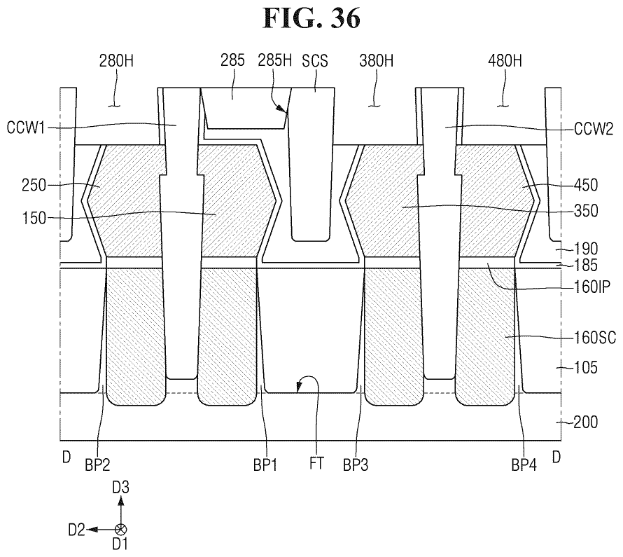

Referring to FIGS. 35 and 36, the upper interlayer insulating films 190 and the source/drain etch stopper films 185 may be removed. As a result, first source/drain contact holes 180H, second source/drain contact holes 280H, third source/drain contact holes 380H, and fourth source/drain contact holes 480H may be formed.

The first source/drain contact holes 180H, the second source/drain contact holes 280H, the third source/drain contact holes 380H, and the fourth source/drain contact holes 480H expose the first source/drain patterns 150, the second source/drain patterns 250, the third source/drain patterns 350, and the fourth source/drain patterns 450, respectively. Since the contact blocking patterns 285 have etch selectivity to the upper interlayer insulating films 190, the first source/drain contact holes 180H are not formed in regions where the contact blocking patterns 285 are formed.

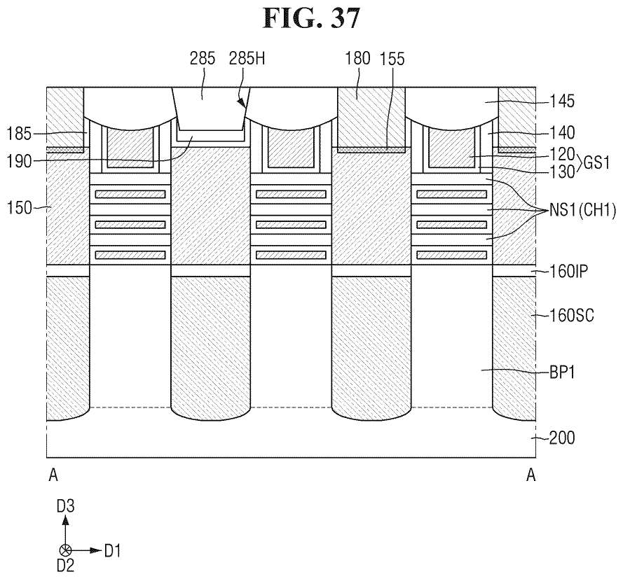

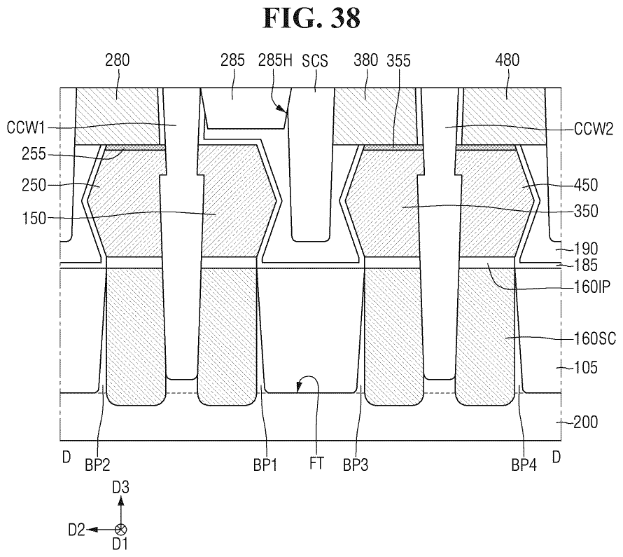

Referring to FIGS. 37 and 38, first source/drain contacts 180, second source/drain contacts 280, third source/drain contacts 380, and fourth source/drain contacts 480 may be formed on the first source/drain patterns 150, the second source/drain patterns 250, the third source/drain patterns 350, and the fourth source/drain patterns 450, respectively.

The first source/drain contacts 180, the second source/drain contacts 280, the third source/drain contacts 380, and the fourth source/drain contacts 480 may be formed within the first source/drain contact holes 180H, the second source/drain contact holes 280H, the third source/drain contact holes 380H, and the fourth source/drain contact holes 480H, respectively. The first source/drain contacts 180, the second source/drain contacts 280, the third source/drain contacts 380, and the fourth source/drain contacts 480 are electrically connected to the first source/drain patterns 150, the second source/drain patterns 250, the third source/drain patterns 350, and the fourth source/drain patterns 450, respectively.

First contact silicide films 155, second contact silicide films 255, third contact silicide films 355, and fourth contact silicide films 455 may be formed between the first source/drain contacts 180, the second source/drain contacts 280, the third source/drain contacts 380, and the fourth source/drain contacts 480 and the first source/drain patterns 150, the second source/drain patterns 250, the third source/drain patterns 350, and the fourth source/drain patterns 450.

Referring to FIGS. 37 through 40, the support substrate 200 may be removed.

The first, second, third, and fourth lower patterns BP1, BP2, BP3, and BP4 and the field insulating film 105 may be exposed. The sacrificial semiconductor patterns 160SC may be exposed.

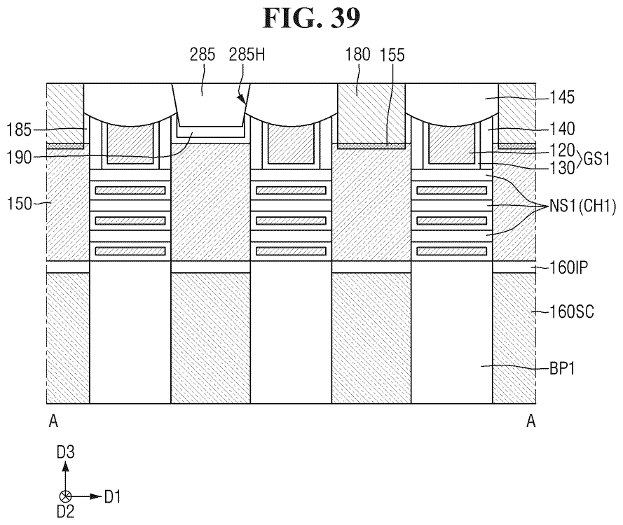

Referring to FIGS. 39 through 42, a backside mask pattern BS_MASK may be formed on the first, second, third, and fourth lower patterns BP1, BP2, BP3, and BP4 and the field insulating film 105.

For example, the backside mask pattern BS_MASK may include openings. The openings of the backside mask pattern BS_MASK may overlap with the sacrificial semiconductor patterns 160SC, which are formed in regions where backside source/drain contacts are to be formed, in a third direction D3.

The sacrificial semiconductor patterns 160SC and the sacrificial pattern capping films 160IP may be removed using the backside mask pattern BS_MASK. As a result, backside source/drain contact holes 175H may be formed. The backside source/drain contact holes 175H may expose the first source/drain patterns 150.

Referring again to FIGS. 2 and 5, the first backside source/drain contacts 175 may be formed within the backside source/drain contact holes 175H. The first backside source/drain contacts 175 may be connected to the first source/drain patterns 150. For example, the first backside source/drain contacts 175 may be connected to first backside connection semiconductor patterns 150_1. First backside contact silicide films 156 may be formed between the first backside source/drain contacts 175 and the first source/drain patterns 150.

By removing the backside mask pattern BS_MASK, the first, second, third, and fourth lower patterns BP1, BP2, BP3, and BP4 and the field insulating film 105 may be exposed. Thereafter, a substrate 100 may be formed. First backside wiring lines 290 and second backside wiring lines 295 may be formed within the substrate 100.

Alternatively, the substrate 100 may be formed with the backside mask pattern BS_MASK still present.

Those skilled in the art will appreciate that the variations and modifications discussed herein may be made to the disclosed embodiments without substantially departing from the principles of the present disclosure.

What is claimed is:

1. A semiconductor device comprising:
a first lower pattern extending in a first direction and comprising a first sidewall, a second sidewall, an upper surface and a lower surface, wherein the first and second sidewalls are opposite to one another in a second direction, and wherein the upper and lower surfaces are opposite to one another in a third direction;
a channel separation structure extending in the first direction and contacting the first sidewall of the first lower pattern;
a field insulating film contacting the second sidewall of the first lower pattern;
a first channel pattern on the upper surface of the first lower pattern, the first channel pattern comprising a plurality of first sheet patterns spaced apart from one another in the third direction, wherein the plurality of first sheet patterns are in contact with the channel separation structure;
a first source/drain pattern in contact with the first channel pattern and the channel separation structure;
a contact blocking pattern on the first source/drain pattern, wherein the contact blocking pattern is formed of an insulating material, and wherein the contact blocking pattern comprises an upper surface on a same plane as an upper surface of the channel separation structure;
a first backside source/drain contact within the first lower pattern and connected to the first source/drain pattern; and
a backside wiring line on the lower surface of the first lower pattern, wherein the backside wiring line is connected to the first backside source/drain contact.

2. The semiconductor device of claim 1, further comprising:
one or more source/drain etch stopper films extending along an upper surface of the field insulating film and sidewalls of the first source/drain pattern; and
one or more interlayer insulating films on the one or more source/drain etch stopper films, wherein the contact blocking pattern is on the one or more interlayer insulating films.

3. The semiconductor device of claim 2, wherein a depth from the upper surface of the channel separation structure to an uppermost portion of the first source/drain pattern is greater than a depth from the upper surface of the channel separation structure to a lower surface of the contact blocking pattern.

4. The semiconductor device of claim 1, further comprising:
a source/drain separation structure on the field insulating film,
wherein the first source/drain pattern is disposed between the source/drain separation structure and the channel separation structure,
wherein an upper surface of the source/drain separation structure is on the same plane as the upper surface of the channel separation structure, and
wherein a depth from the upper surface of the channel separation structure to a lower surface of the source/drain separation structure is greater than or equal to a depth from the upper surface of the channel separation structure to a lower surface of the contact blocking pattern.

5. The semiconductor device of claim 4, further comprising:
a gate structure on the first lower pattern, wherein the gate structure is in contact with the channel separation structure; and
a gate separation structure on the field insulating film, wherein the gate separation structure is in contact with the gate structure,
wherein the gate structure is between the gate separation structure and the channel separation structure,
wherein an upper surface of the source/drain separation structure is on a same plane as an upper surface of the gate separation structure, and
wherein a height of the source/drain separation structure is less than a height of the gate separation structure.

6. The semiconductor device of claim 1, further comprising:
a gate structure on the first lower pattern, wherein the gate structure is in contact with the channel separation structure; and
a gate separation structure on the field insulating film and extending in the first direction,
wherein the gate structure and the first source/drain pattern are between the channel separation structure and the gate separation structure.

7. The semiconductor device of claim 1, further comprising:
a second lower pattern spaced apart from the first lower pattern in the second direction and extending in the first direction;
a second channel pattern on an upper surface of the second lower pattern, the second channel pattern comprising a plurality of second sheet patterns, wherein the plurality of second sheet patterns are spaced apart from one another in the third direction;
a second source/drain pattern in contact with the second channel pattern and the channel separation structure; and
a source/drain contact on and connected to the second source/drain pattern,
wherein the second lower pattern is in contact with the channel separation structure,
wherein the plurality of second sheet patterns is in contact with the channel separation structure,
wherein an upper surface of the source/drain contact is on a same plane as the upper surface of the channel separation structure, and
wherein the source/drain contact is not connected to the backside wiring line.

8. The semiconductor device of claim 7, further comprising:
a sacrificial semiconductor pattern within the second lower pattern,
wherein the second source/drain pattern is between the sacrificial semiconductor pattern and the source/drain contact.

9. The semiconductor device of claim 1, further comprising:
a second lower pattern spaced apart from the first lower pattern in the second direction and extending in the first direction;
a second channel pattern on an upper surface of the second lower pattern, the second channel pattern comprising a plurality of second sheet patterns, wherein the plurality of second sheet patterns are spaced apart from one another in the third direction;
a second source/drain pattern in contact with the second channel pattern and the channel separation structure;
a second backside source/drain contact within the second lower pattern, wherein the second backside source/drain contact is connected to the second source/drain pattern; and
a second backside wiring line on the lower surface of the first lower pattern, wherein the second backside source/drain contact is connected to the second backside wiring line.

10. The semiconductor device of claim 1, further comprising:
a lower insulating pattern between the first lower pattern and the first channel pattern, wherein the lower insulating pattern is in contact with the upper surface of the first lower pattern.

11. The semiconductor device of claim 1,
wherein in a region where the channel separation structure contacts the first source/drain pattern, the channel separation structure comprises a first portion and a second portion,
wherein a width, in the second direction, of the channel separation structure increases away from a lower surface of the field insulating film,
wherein the second portion of the channel separation structure is on the first portion of the channel separation structure, and
wherein a width of an uppermost part of the first portion of the channel separation structure is greater than a width of a lowermost part of the second portion of the channel separation structure.

12. The semiconductor device of claim 11, wherein a height from the lower surface of the field insulating film to the uppermost part of the first portion of the channel separation structure is less than a height from the lower surface of the field insulating film to an uppermost portion of the first source/drain pattern.

13. The semiconductor device of claim 12, wherein a portion of the first source/drain pattern overlaps with the first portion of the channel separation structure in the third direction.

14. The semiconductor device of claim 1, wherein a depth from the upper surface of the first lower pattern to a lowermost portion of the channel separation structure is less than or equal to a depth from the upper surface of the first lower pattern to a lower surface of the field insulating film.

15. A semiconductor device comprising:
a first channel separation structure extending in a first direction;
a second channel separation structure spaced apart from the first channel separation structure in a second direction and extending in the first direction;
a first lower pattern between the first and second channel separation structures, contacting the first channel separation structure, and comprising a first upper surface and a first lower surface, wherein the first upper surface and the first lower surface are opposite to each other;
a second lower pattern between the first and second channel separation structures, wherein the second lower pattern is in contact with the second channel separation structure, extends in the first direction, and comprises a second upper surface and a second lower surface, wherein the first upper surface and the second lower surface are opposite to each other;
a field insulating film between the first and second lower patterns;
a first channel pattern on the first upper surface, the first channel pattern comprising a plurality of first sheet patterns spaced apart from one another in a third direction, wherein the plurality of first sheet patterns are in contact with the first channel separation structure;
a second channel pattern on the second upper surface, the second channel pattern comprising a plurality of second sheet patterns spaced apart from one another in the third direction, wherein the plurality of second sheet patterns are in contact with the second channel separation structure;
a first source/drain pattern in contact with the first channel pattern and the first channel separation structure;
a second source/drain pattern in contact with the second channel pattern and the second channel separation structure;
a source/drain separation structure between the first source/drain pattern and the second source/drain pattern, the source/drain separation structure comprising an upper surface on a same plane as an upper surface of the first channel separation structure;
a contact blocking pattern on the first source/drain pattern, wherein the contact blocking pattern is formed of an insulating material, and wherein the contact blocking pattern comprises an upper surface on the same plane as the upper surface of the first channel separation structure;
a source/drain contact on and connected to the second source/drain pattern, wherein the source/drain contact comprises an upper surface on a same plane as an upper surface of the second channel separation structure;
a backside source/drain contact within the first lower pattern and connected to the first source/drain pattern; and
a backside wiring line on the first and second lower surfaces, wherein the backside wiring line is connected to the backside source/drain contact.

16. The semiconductor device of claim 15, further comprising:
a sacrificial semiconductor pattern within the second lower pattern,
wherein the second source/drain pattern is between the sacrificial semiconductor pattern and the source/drain contact.

17. The semiconductor device of claim 15, wherein the source/drain contact is not connected to the backside wiring line.

18. The semiconductor device of claim 15, wherein the contact blocking pattern does not contact the first source/drain pattern.

19. The semiconductor device of claim 15, further comprising:
a first lower insulating pattern between the first lower pattern and the first channel pattern, wherein the first lower insulating pattern is in contact with the first upper surface; and
a second lower insulating pattern between the second lower pattern and the first channel pattern, wherein the second lower insulating pattern is in contact with the second upper surface.

20. A semiconductor device comprising:
a lower pattern extending in a first direction and comprising an upper surface and a lower surface, wherein the upper and lower surfaces are opposite to each other in a second direction;
a channel separation structure extending in the first direction and contacting the lower pattern;
a channel pattern on the upper surface of the lower pattern, the channel pattern comprising a plurality of sheet patterns spaced apart from one another in the second direction, wherein the plurality of sheet patterns are in contact with the channel separation structure;
a first source/drain pattern on the lower pattern and in contact with the channel pattern;
a second source/drain pattern on the lower pattern, wherein the second source/drain pattern is in contact with the channel pattern and the channel separation structure and is spaced apart from the first source/drain pattern in the first direction;
a gate structure between the first source/drain pattern and the second source/drain pattern, wherein the gate structure is on the lower pattern and is in contact with the channel separation structure;
a contact blocking pattern on the first source/drain pattern, wherein the contact blocking pattern is formed of an insulating material, and wherein the contact blocking pattern comprises an upper surface on a same plane as an upper surface of the channel separation structure;
a source/drain contact on and connected to the second source/drain pattern, the source/drain contact comprising an upper surface on a same plane as the upper surface of the contact blocking pattern;
a backside source/drain contact within the lower pattern and connected to the first source/drain pattern; and
a backside wiring line on the lower surface of the lower pattern, wherein the backside wiring line is connected to the backside source/drain contact.
